(19) United States
(12) Patent Application Publication
(10) Pub. No.: US 2013/0168645 A1
(43) Pub. Date: Jul. 4, 2013

(54) GREEN ORGANIC LIGHT-EMITTING DIODE, AND FLAT PANEL DISPLAY DEVICE INCLUDING THE SAME

(71) Applicant: Mie-Hwa Park, Yongin-si (KR)

(72) Inventor: Mie-Hwa Park, Yongin-si (KR)

(21) Appl. No.: 13/591,202

(22) Filed: Aug. 21, 2012

(30) Foreign Application Priority Data
Dec. 30, 2011 (KR) 10-2011-0147426

(51) Int. Cl. H01L 51/54

(52) U.S. Cl. 257/40; 257/E51.026

(57) ABSTRACT

An organic light-emitting diode includes: a first electrode, a second electrode facing the first electrode, an emission layer between the first and second electrodes and including a first compound and a second compound, and a first organic layer between the emission layer and the first electrode and including a third compound, wherein the first compound is represented by Formula 1 below, the second compound is represented by Formula 2 below, and the third compound is represented by Formula 3a or 3b below.

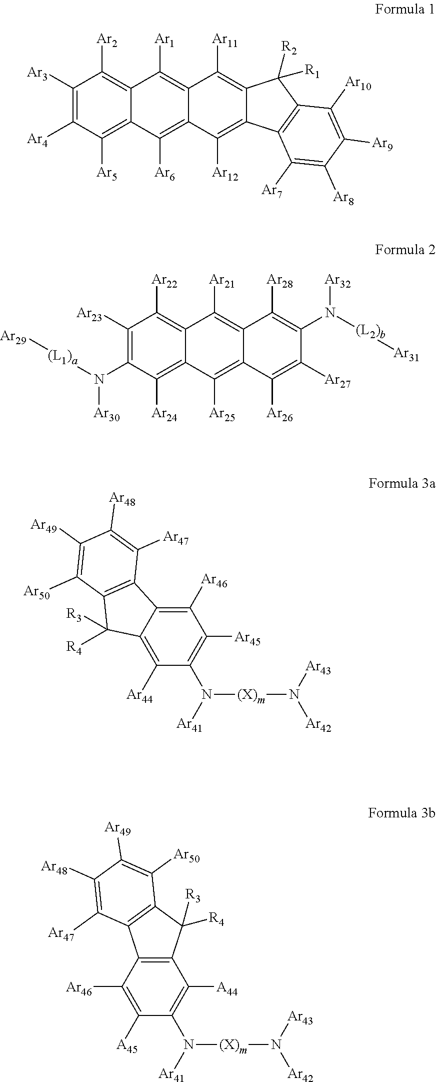

### CROSS-REFERENCE TO RELATED PATENT APPLICATION

This application claims priority to and the benefit of Korean Patent Application No. 10-2011-0147426, filed on Dec. 30, 2011 in the Korean Intellectual Property Office, the entire content of which is incorporated herein by reference.

### BACKGROUND

1. Technical Field

The present invention relates to a green organic light-emitting diode and a flat panel display device including the same, and more particularly, to an organic light-emitting diode including materials with good thermal stability, and to a flat panel display device including the organic light-emitting diode.

2. Description of the Related Art

Organic light emitting diodes (OLEDs) are self-emission devices, and have wide viewing angles, high contrast ratios, short response times, and good brightness, driving voltage, and response speed characteristics. Also, OLEDs enable generation of multi-colored images. Due to these advantages, organic light-emitting diodes are getting much attention.

In a typical organic light-emitting diode, an anode is formed on a substrate, and a hole transport layer, an emission layer, an electron transport layer, and a cathode are formed in sequential order on the anode. In this regard, the hole transport layer, the emission layer, and the electron transport layer are organic films including organic compounds. When a voltage is applied between the anode and the cathode, holes injected from the anode pass through the hole transport layer and migrate toward the emission layer, and electrons injected from the cathode pass through the electron transport layer and migrate toward the emission layer. The holes and electrons, which are carriers, are recombined in the emission layer to generate excitons, and then the excitons change from an excited state to a ground state, thereby generating light.

Organic layers of organic light-emitting diodes are mainly composed of organic materials. However, the thermal stability of the organic materials decreases over time, and thus, the lifespan of an organic light-emitting diode including organic materials gradually decreases.

Thus, there is a need to improve the hole injection characteristics and thermal stability, as well as the luminescent efficiency of the emission layer.

### SUMMARY OF THE INVENTION

Embodiments of the present invention provide a green organic light-emitting diode having improved hole injection and mobility characteristics, and improved thermal stability at the boundary of the emission layer. Other embodiments provide a flat panel display device including the organic light-emitting diode.

According to an aspect of the present invention, an organic light-emitting diode includes: a first electrode, a second electrode facing the first electrode, an emission layer between the first and second electrodes and including a first compound and a second compound, and a first organic layer between the emission layer and the first electrode that includes a third compound, wherein the first compound is represented by Formula 1 below, the second compound is represented by Formula 2 below, and the third compound is represented by Formula 3a or 3b below:

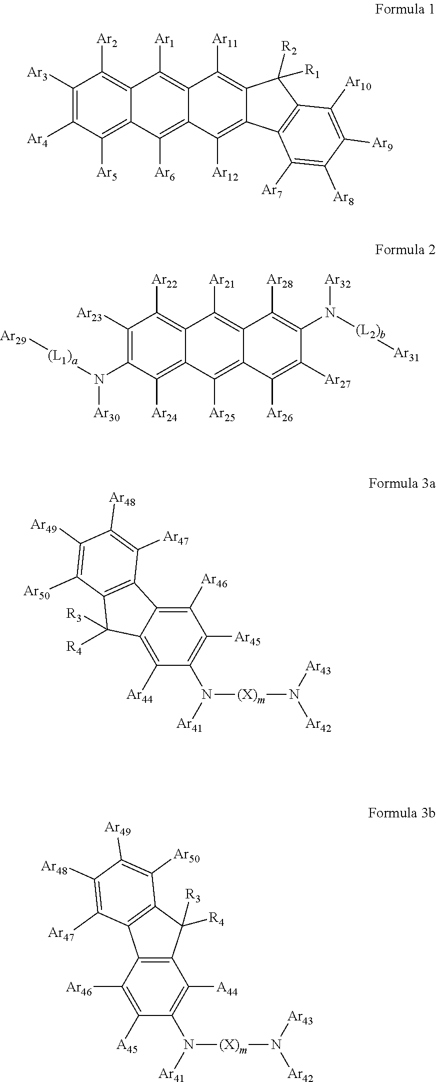

In Formulae 1, 2, 3a and 3b, each of Ar₁ to Ar₁₂, Ar₂₁ to Ar₃₂ and Ar₄₁ to Ar₅₀ may independently be one of a hydrogen atom, a deuterium atom, a halogen atom, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, a substituted or unsubstituted C₅-C₃₀ aryloxy group, a substituted or unsubstituted C₅-C₃₀ arylthio group, a substituted or unsubstituted C₂-C₃₀ heteroaryl group, or a group represented by N(Q₁)(Q₂), where each of Q₁ and Q₂ may be independently one of a hydrogen atom, a deuterium atom, a halogen atom, a hydroxyl group, a cyano group, an amino group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, a substituted or unsubstituted C₅-C₃₀ aryloxy group, a substituted or unsubstituted C₅-C₃₀ arylthio group, or a substituted or unsubstituted C₂-C₃₀ heteroaryl group. At least one of Ar₂₉ to Ar₃₂ is a fluorenyl group.

Each of R₁ to R₄ may be independently one of a hydrogen atom, a deuterium atom, a halogen atom, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, and a substituted or unsubstituted C₂-C₃₀ heteroaryl group.

Each of L₁, L₂, and X may be independently one of a substituted or unsubstituted C₅-C₆₀ arylene group or a substituted or unsubstituted C₂-C₃₀ heteroarylene group, where X may optionally bind to Ar₄₂ or Ar₄₃ to form a ring.

Each of a and b may be independently an integer of 0 to 3, and m may be an integer of 1 to 3.

Each of Ar₁ to Ar₁₂, Ar₂₁ to Ar₃₂ and Ar₄₁ to Ar₅₀ may be independently one of a substituted or unsubstituted C₁-C₃₀ alkyl group, a substituted or unsubstituted C₅-C₃₀ aryl group, or a substituted or unsubstituted C₂-C₃₀ heteroaryl group.

Each of R₁ to R₄ may be independently one of a substituted or unsubstituted C₁-C₃₀ alkyl group, a substituted or unsubstituted C₅-C₃₀ aryl group, or a substituted or unsubstituted C₂-C₃₀ heteroaryl group.

The first compound may be represented by Formula 4 below:

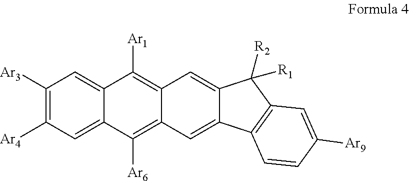

In Formula 4, each of Ar₁, Ar₃, Ar₄, Ar₆ and Ar₉ may be independently one of a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted carbazolyl group, a substituted or unsubstituted dibenzofuranyl group, a substituted or unsubstituted dibenzothiophenyl group, and a substituted or unsubstituted benzocarbazolyl group. Each of R₁ and R₂ may be independently one of a substituted or unsubstituted methyl group, a substituted or unsubstituted ethyl group, a substituted or unsubstituted propyl group, a substituted or unsubstituted butyl group, or a substituted or unsubstituted phenyl group.

The second compound may be a compound represented by one of Formulae 5a to 5h below:

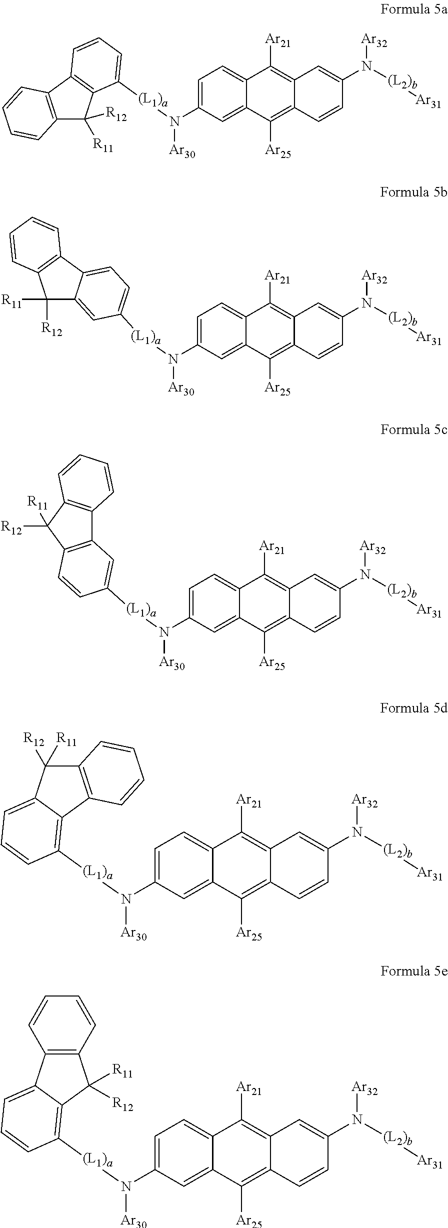

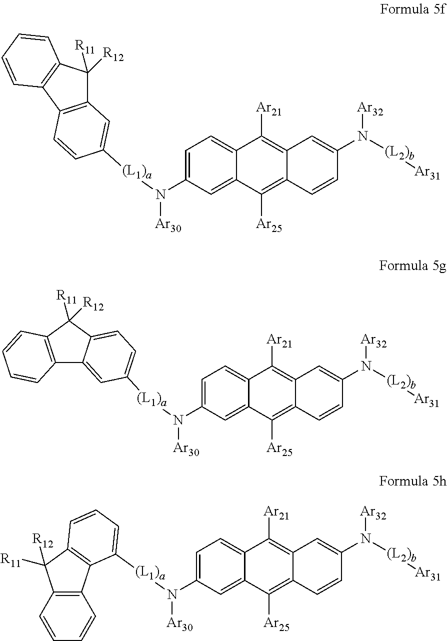

In Formulae 5a to 5h, each of Ar₂₁, Ar₂₅, Ar₃₀, Ar₃₁, and Ar₃₂ may be independently one of a hydrogen atom, a deuterium atom, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted indolyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group. Each of R₁₁ and R₁₂ may be independently one of a substituted or unsubstituted methyl group, a substituted or unsubstituted ethyl group, a substituted or unsubstituted propyl group, a substituted or unsubstituted butyl group, or a substituted or unsubstituted phenyl group. Each of L₁ and L₂ may be independently one of a substituted or unsubstituted phenylene group, a substituted or unsubstituted biphenylene group, a substituted or unsubstituted naphthylene group, a substituted or unsubstituted anthrylene group, a substituted or unsubstituted phenanthrenylene group, or a substituted or unsubstituted fluorenylene group. Each of a and b may be independently an integer of 0 or 1.

The third compound may be a compound represented by Formula 6a or 6b below:

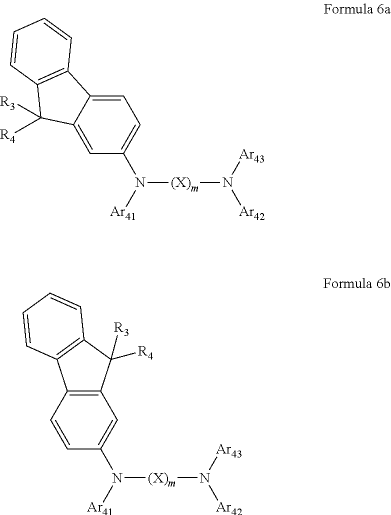

In Formulae 6a and 6b, each of Ar₄₁, Ar₄₂ and Ar₄₃ may be independently one of a hydrogen atom, a deuterium atom, a halogen atom, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group. Each of R₃ and R₄ may be independently one of a substituted or unsubstituted methyl group, a substituted or unsubstituted ethyl group, a substituted or unsubstituted propyl group, a substituted or unsubstituted butyl group, or a substituted or unsubstituted phenyl group. X may be one of a substituted or unsubstituted phenylene group, a substituted or unsubstituted biphenylene group, a substituted or unsubstituted naphthylene group, a substituted or unsubstituted anthrylene group, a substituted or unsubstituted phenanthrenylene group, and a substituted or unsubstituted fluorenylene group, where X may optionally bind to Ar₄₂ or Ar₄₃ to form a ring, and m may be an integer of 1 or 2.

A highest occupied molecular orbital (HOMO) energy level of the third compound may be lower than −5.4 eV.

An amount of the third compound may be about 30 to about 100 parts by weight based on 100 parts by weight of the first organic layer.

The first organic layer may include at least one of a hole injection layer, a hole transport layer, and a functional layer having both hole injection and hole transport functions.

The first organic layer may be a hole transport layer, and a hole injection layer may be formed between the first organic layer and the first electrode.

The first organic layer may further include a charge generation material, and the charge generation material may include at least one of a quinone derivative, a metal oxide, and a cyano group-containing compound.

The first organic layer may be formed using a wet process.

The first compound may be a fluorescent host material, and the second compound may be a fluorescent dopant material.

The emission layer may include a green emission layer.

The organic light-emitting diode may include, between the emission layer and the second electrode, at least one of an electron injection layer, an electron transport layer, and a functional layer having both electron injection and electron transport functions.

The at least one of an electron injection layer, an electron transport layer, and a functional layer having both electron injection and electron transport functions may include an electron transport material and a metal complex.

According to another aspect of the present invention, a flat panel display device includes: a transistor including a source, a drain, a gate, and an activation layer; and the organic light-emitting diode, where the first electrode of the organic light-emitting diode is electrically connected to any one of the source or the drain.

### BRIEF DESCRIPTION OF THE DRAWINGS

The above and other features and advantages of the present invention will become more apparent by reference to the following detailed description when considered in conjunction with the drawing, in which:

FIG. 1 which is a schematic view of an organic light-emitting diode according to an embodiment of the present invention.

### DETAILED DESCRIPTION OF THE INVENTION

Expressions such as “one of,” when preceding a list of elements, modify the entire list of elements and do not modify the individual elements of the list.

An organic light-emitting diode according to an embodiment of the present invention includes: a first electrode, a second electrode facing the first electrode, an emission layer between the first and second electrodes including a first compound and a second compound, and a first organic layer between the emission layer and the first electrode including a third compound, where the first compound is represented by Formula 1 below, the second compound is represented by Formula 2 below, and the third compound is represented by Formula 3a or 3b below:

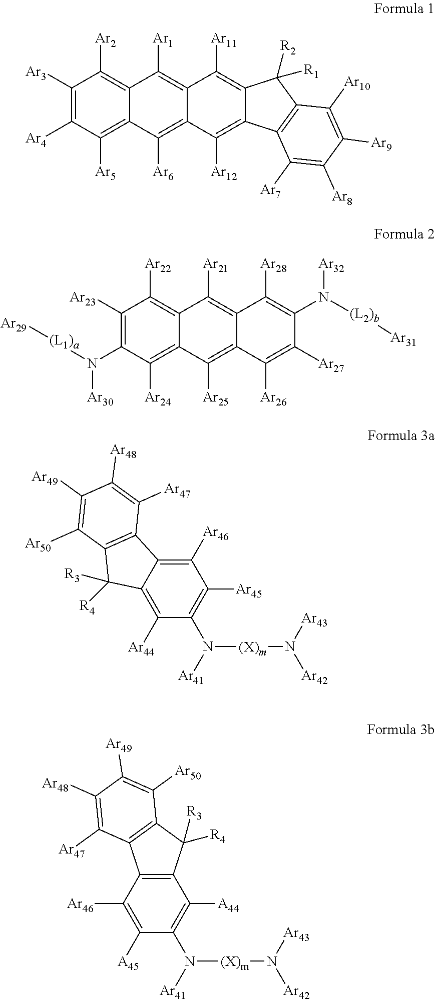

In Formulae 1, 2, 3a, and 3b, each of Ar₁ to Ar₁₂, Ar₂₁ to Ar₃₂, and Ar₄₁ to Ar₅₀ may be independently one of a hydrogen atom, a deuterium atom, a halogen atom, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, a substituted or unsubstituted C₅-C₃₀ aryloxy group, a substituted or unsubstituted C₅-C₃₀ arylthio group, a substituted or unsubstituted C₂-C₃₀ heteroaryl group, or a group represented by N(Q₁)(Q₂), where each of Q₁ and Q₂ may be independently one of a hydrogen atom, a deuterium atom, a halogen atom, a hydroxyl group, a cyano group, an amino group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, a substituted or unsubstituted C₅-C₃₀ aryloxy group, a substituted or unsubstituted C₅-C₃₀ arylthio group, or a substituted or unsubstituted C₂-C₃₀ heteroaryl group. In some embodiments, at least one of Ar₂₉ to Ar₃₂ is a fluorenyl group. Each of R₁ to R₄ may be independently one of a hydrogen atom, a deuterium atom, a halogen atom, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, or a substituted or unsubstituted C₂-C₃₀ heteroaryl group. Each of L₁, L₂ and X may be independently one of a substituted or unsubstituted C₅-C₆₀ arylene group, or a substituted or unsubstituted C₂-C₃₀ heteroarylene group. X may optionally bind to Ar₄₂ or Ar₄₃ to form a ring. Each of a and b may be independently an integer of 0 to 3, and m may be an integer of 1 to 3.

In the formulae above, when a is 2 or more, a plurality of L₁ are present and the plurality of L₁ may be identical to or different from each other. Similarly, when b is 2 or more, a plurality of L₂ are present and the plurality of L₂ may be identical to or different from each other. Likewise, when m is 2 or more, a plurality of X may be present and the plurality of X may be identical to or different from each other.

The first compound and the second compound included in the emission layer of the organic light-emitting diode each include a fluorene unit, and the third compound included in the first organic layer between the emission layer and the first electrode also includes a fluorene unit. Because all of the first compound, the second compound, and the third compound include a fluorene unit, the first, second, and third compounds have high glass transition temperatures (Tg) and good thermal stability.

Because the emission layer and the first organic layer of the organic light-emitting diode include compounds with good thermal stability, the thermal stability between the emission layer and the first organic layer is improved, and injection of holes from the first electrode to the emission layer is smoothly performed. Thus, even when the organic light-emitting diode is continuously driven, heat generation due to resistance inside the organic light-emitting diode is suppressed, and uniform quality of each layer may be maintained. Thus, crystallization of the organic layer including the emission layer is prevented, and thus, the efficiency and lifespan of the formed organic light-emitting diode are increased.

In particular, like the organic light-emitting diode, when the emission layer including the first compound and the second compound and the first organic layer including the third compound are simultaneously included in an organic light-emitting diode, the efficiency and lifespan of the organic light-emitting diode are substantially increased.

The first compound is represented by Formula 1, and due to its high Tg and good thermal stability, it may be used as a light-emitting material in the emission layer of an organic light-emitting diode:

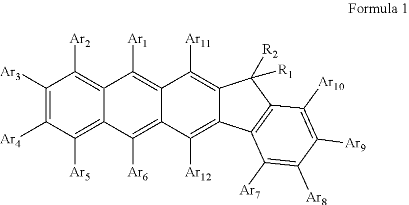

In Formula 1 above, Ar₁ to Ar₁₂, and R₁ and R₂ are the same as defined above.

In some embodiments, each of Ar₁ to Ar₁₂ may be independently one of a substituted or unsubstituted C₁-C₃₀ alkyl group, a substituted or unsubstituted C₅-C₃₀ aryl group, or a substituted or unsubstituted C₂-C₃₀ heteroaryl group.

In some embodiments, each of R₁ and R₂ may be independently one of a substituted or unsubstituted C₁-C₃₀ alkyl group, a substituted or unsubstituted C₅-C₃₀ aryl group, or a substituted or unsubstituted C₂-C₃₀ heteroaryl group.

For example, the first compound may be a compound represented by Formula 4:

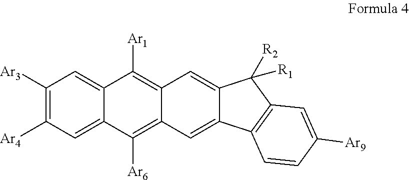

In Formula 4, each of Ar₁, Ar₃, Ar₄, Ar₆, and Ar₉ may be independently one of a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group. Each of R₁ and R₂ may be independently one of a substituted or unsubstituted methyl group, a substituted or unsubstituted ethyl group, a substituted or unsubstituted propyl group, a substituted or unsubstituted butyl group, and a substituted or unsubstituted phenyl group.

For example, the first compound may be one of Compounds 11 to 20, but is not limited thereto:

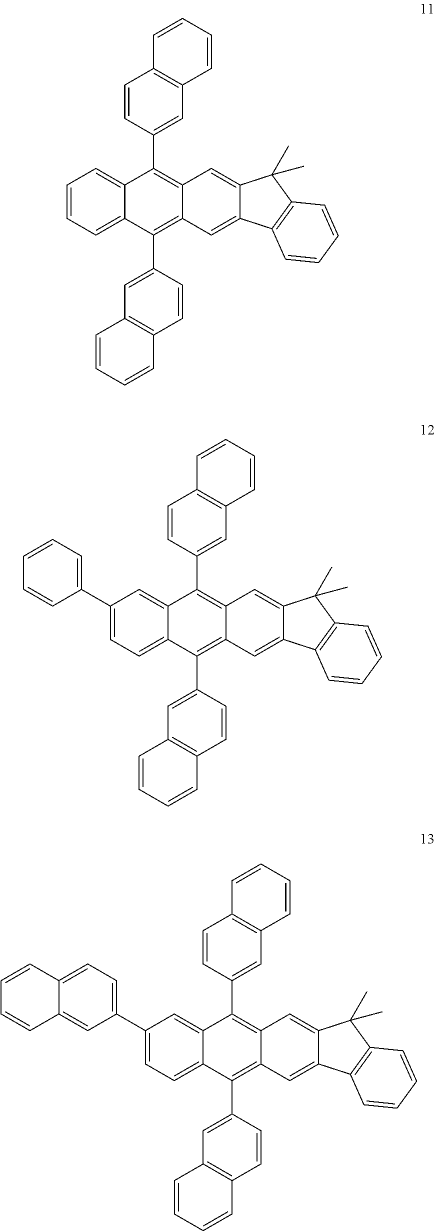

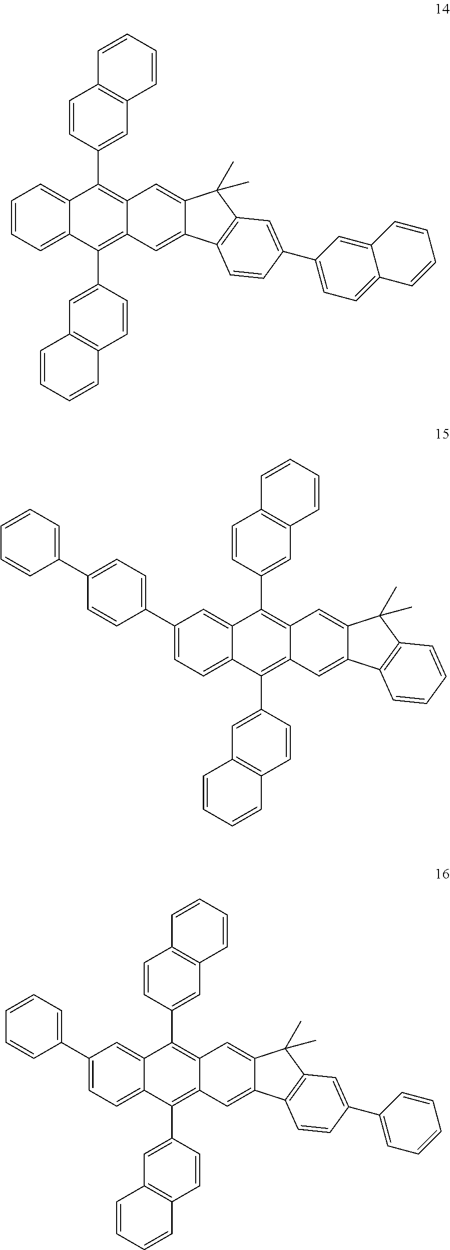

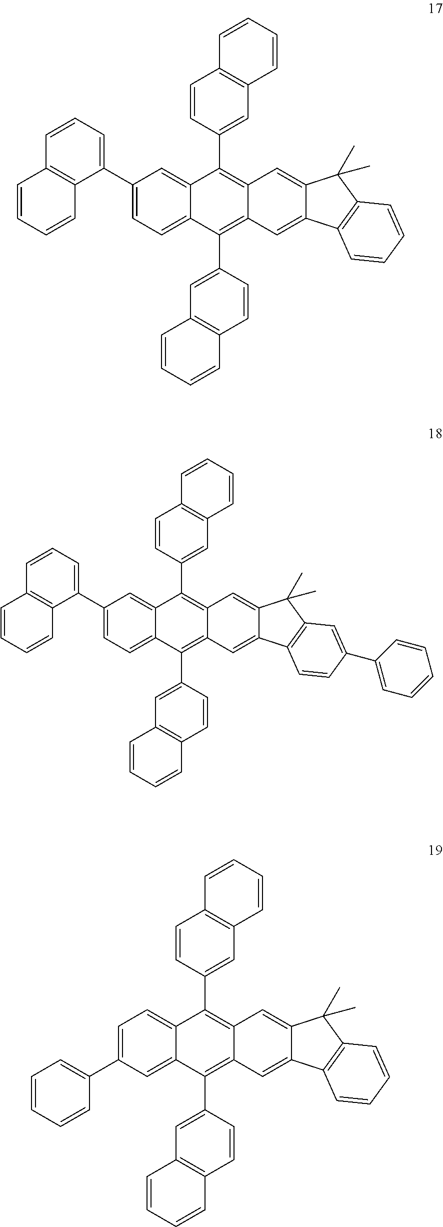

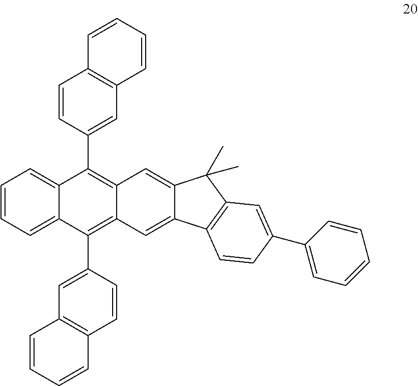 [SMILES: CC1(C)c2cc(-c3ccccc3)ccc2-c2cc3c(-c4ccc5ccccc5c4)c4ccccc4c(-c4ccc5ccccc5c4)c3cc21]

The second compound may be represented by Formula 2, and due to its high Tg and good thermal stability, it may be used as a light-emitting material in the emission layer of an organic light-emitting diode:

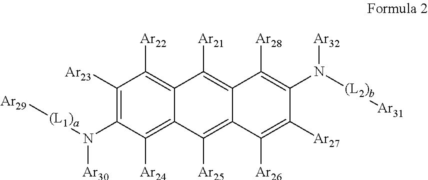

In Formula 2, Ar₂₁ to Ar₃₂, L₁, L₂, and a and b are the same as defined above. At least one of Ar₂₉ to Ar₃₂ is a fluorenyl group, and thus, the compound represented by Formula 2 includes at least one fluorene group.

For example, each of Ar₂₁ to Ar₃₂ may be independently one of a substituted or unsubstituted C₁-C₃₀ alkyl group, a substituted or unsubstituted C₅-C₃₀ aryl group, or a substituted or unsubstituted C₂-C₃₀ heteroaryl group.

The second compound may be a compound represented by one of Formulae 5a to 5h below:

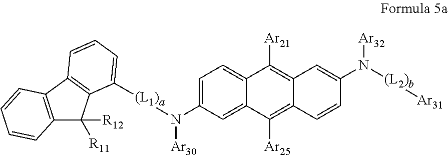

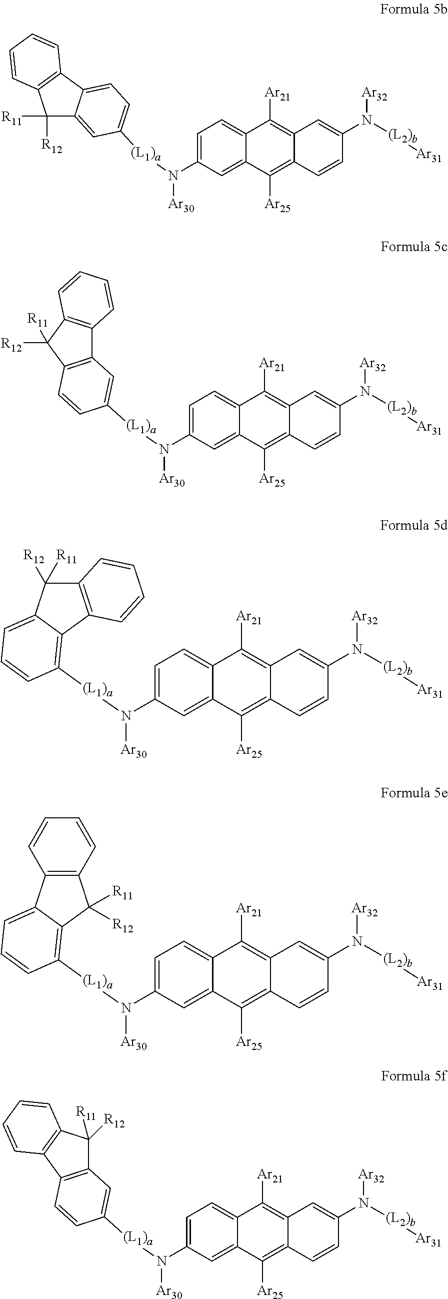

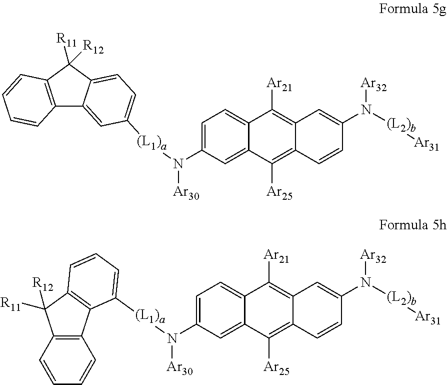

In Formulae 5a to 5h, each of Ar₂₁, Ar₂₅, Ar₃₀, Ar₃₁ and Ar₃₂ may be independently one of a hydrogen atom, a deuterium atom, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted indolyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group. Each of R₁₁ and R₁₂ may be independently one of a substituted or unsubstituted methyl group, a substituted or unsubstituted ethyl group, a substituted or unsubstituted propyl group, a substituted or unsubstituted butyl group, or a substituted or unsubstituted phenyl group. Each of L₁ and L₂ may be independently one of a substituted or unsubstituted phenylene group, a substituted or unsubstituted biphenylene group, a substituted or unsubstituted naphthylene group, a substituted or unsubstituted anthrylene group, a substituted or unsubstituted phenanthrenylene group, or a substituted or unsubstituted fluorenylene group. Each of a and b may be independently an integer of 0 or 1.

For example, the second compound may be any one of Compounds 31 to 45 below, but is not limited thereto:

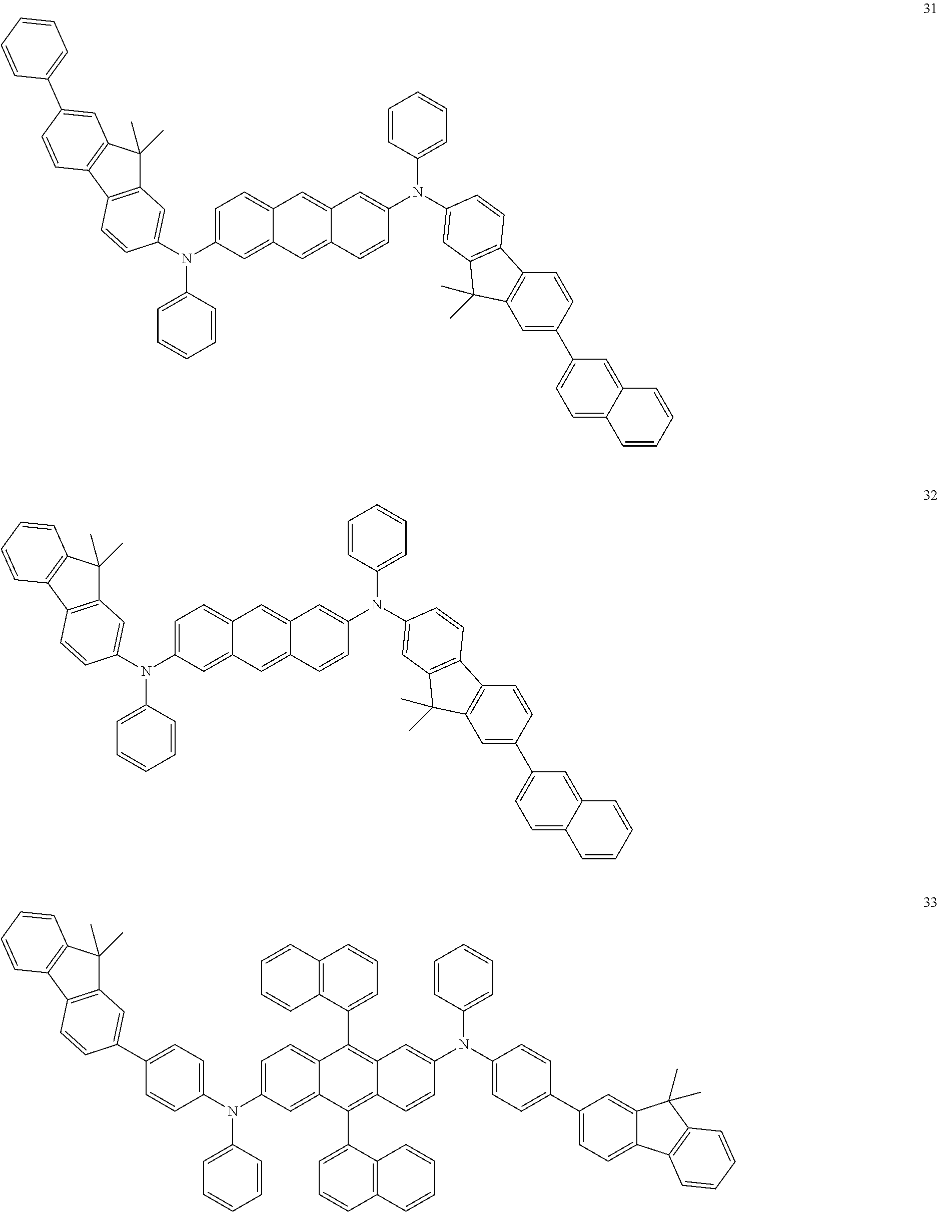 [SMILES: CC1(C)c2cc(-c3ccccc3)ccc2-c2ccc(N(c3ccccc3)c3ccc4cc5cc(N(c6ccccc6)c6ccc7c(c6)C(C)(C)c6cc(-c8ccc9ccccc9c8)ccc6-7)ccc5cc4c3)cc21 ; CC1(C)c2ccccc2-c2ccc(N(c3ccccc3)c3ccc4cc5cc(N(c6ccccc6)c6ccc7c(c6)C(C)(C)c6cc(-c8ccc9ccccc9c8)ccc6-7)ccc5cc4c3)cc21 ; CC1(C)c2ccccc2-c2ccc(-c3ccc(N(c4ccccc4)c4ccc5c(-c6cccc7ccccc67)c6cc(N(c7ccccc7)c7ccc(-c8ccc9c(c8)C(C)(C)c8ccccc8-9)cc7)ccc6c(-c6cccc7ccccc67)c5c4)cc3)cc21]

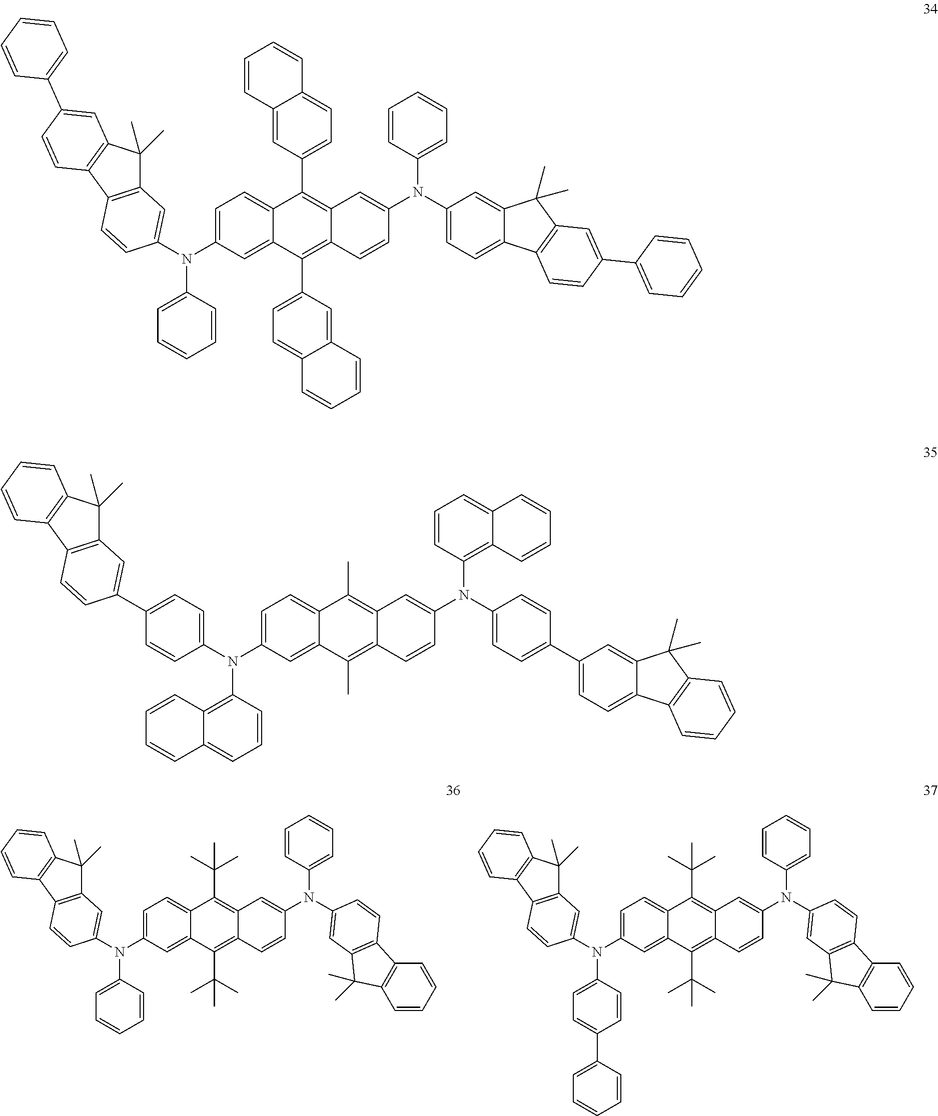

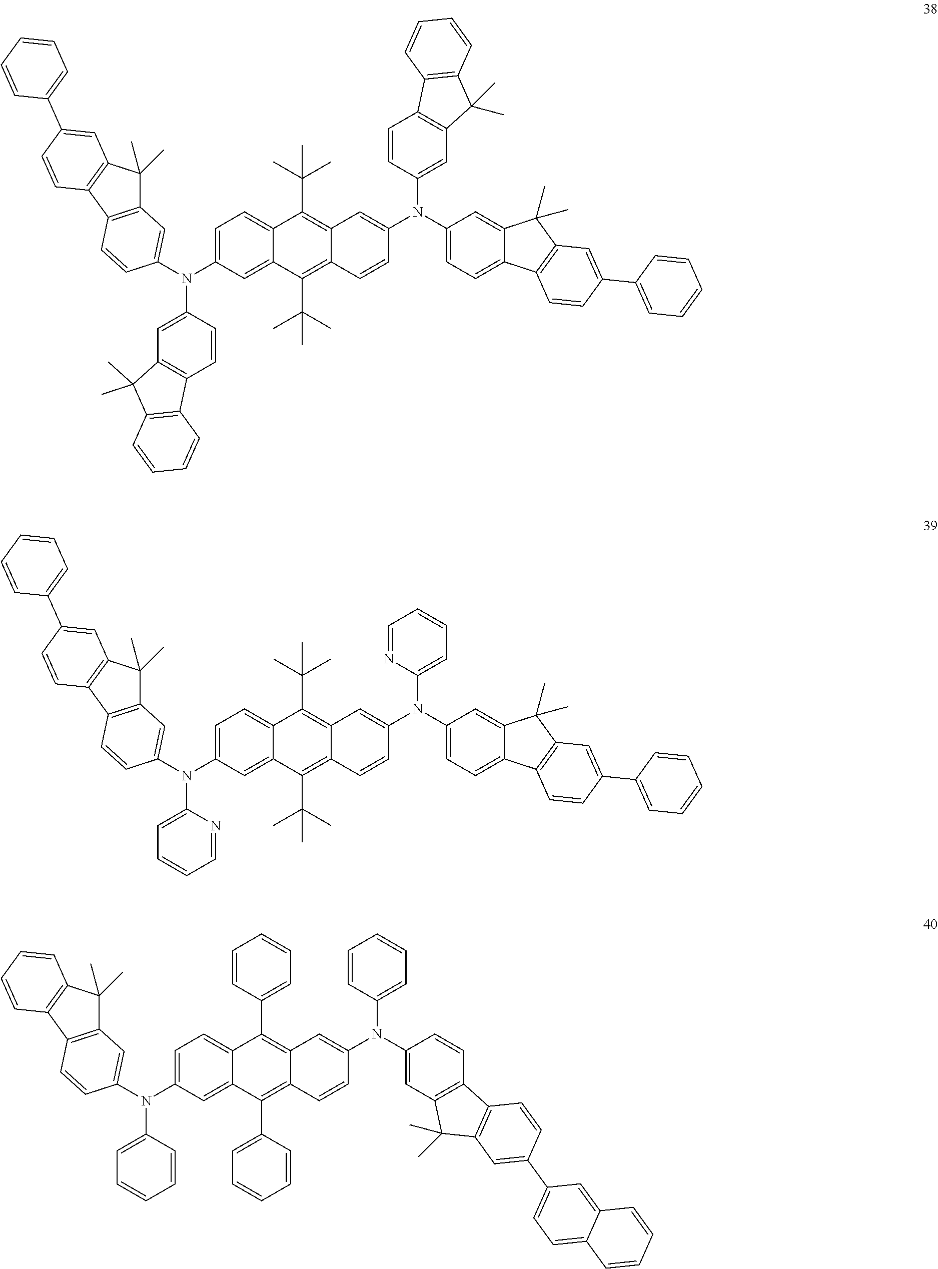 [SMILES: CC(C)(C)c1c2ccc(N(c3ccc4c(c3)C(C)(C)c3ccccc3-4)c3ccc4c(c3)C(C)(C)c3cc(-c5ccccc5)ccc3-4)cc2c(C(C)(C)C)c2ccc(N(c3ccc4c(c3)C(C)(C)c3ccccc3-4)c3ccc4c(c3)C(C)(C)c3cc(-c5ccccc5)ccc3-4)cc12 ; CC(C)(C)c1c2ccc(N(c3ccc4c(c3)C(C)(C)c3cc(-c5ccccc5)ccc3-4)c3ccccn3)cc2c(C(C)(C)C)c2ccc(N(c3ccc4c(c3)C(C)(C)c3cc(-c5ccccc5)ccc3-4)c3ccccn3)cc12 ; CC1(C)c2ccccc2-c2ccc(N(c3ccccc3)c3ccc4c(-c5ccccc5)c5cc(N(c6ccccc6)c6ccc7c(c6)C(C)(C)c6cc(-c8ccc9ccccc9c8)ccc6-7)ccc5c(-c5ccccc5)c4c3)cc21]

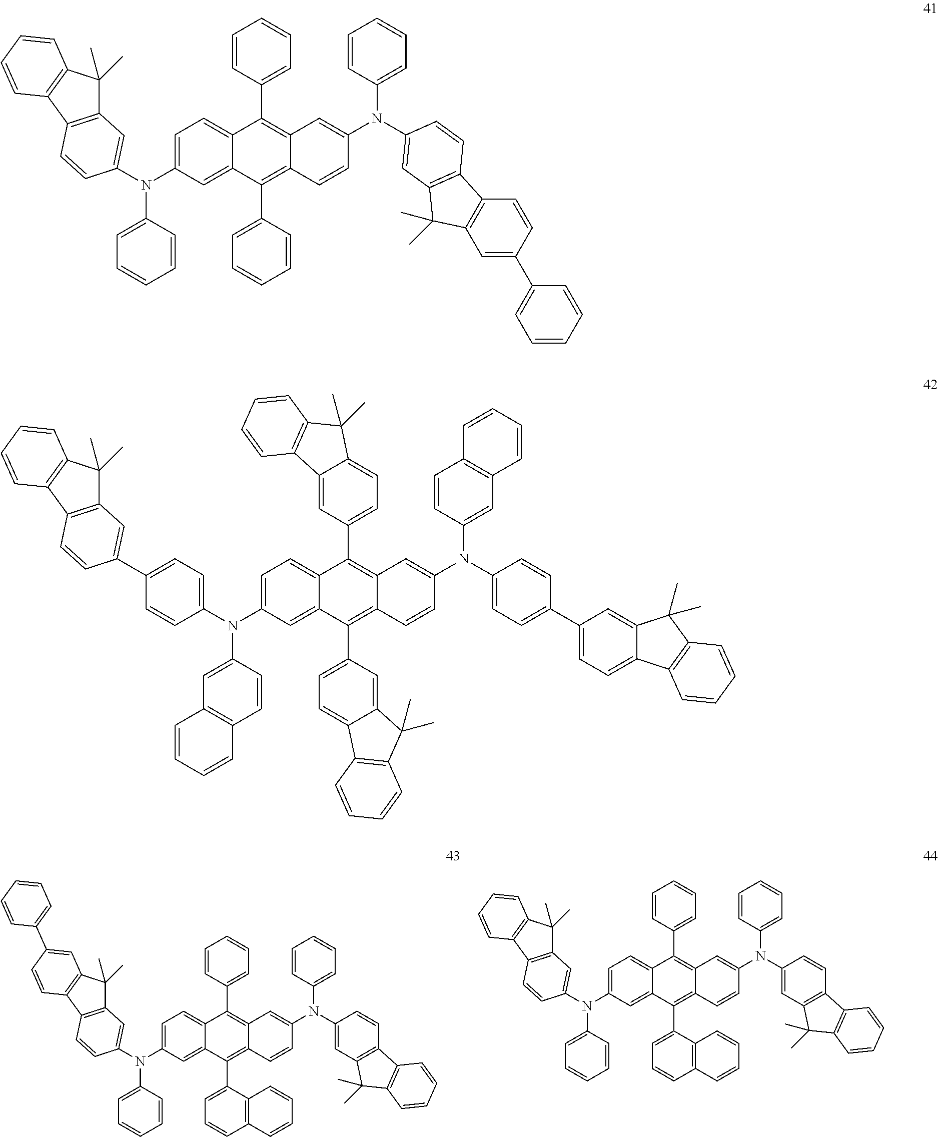

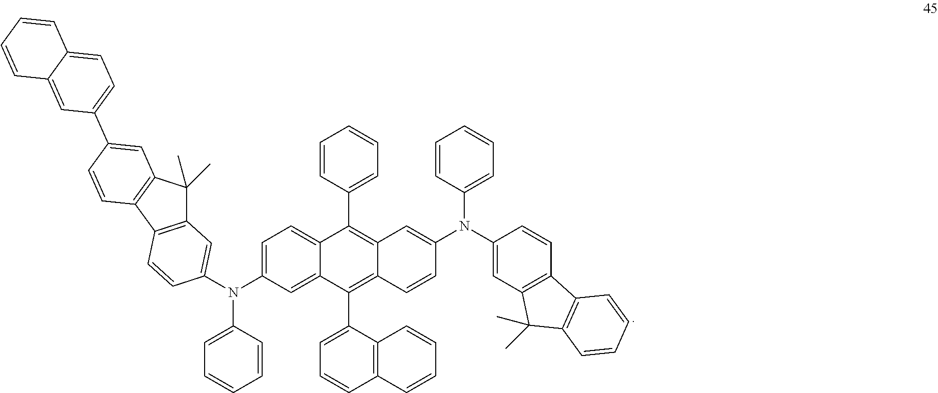 [SMILES: CC1(C)c2ccccc2-c2ccc(N(c3ccccc3)c3ccc4c(-c5cccc6ccccc56)c5cc(N(c6ccccc6)c6ccc7c(c6)C(C)(C)c6cc(-c8ccc9ccccc9c8)ccc6-7)ccc5c(-c5ccccc5)c4c3)cc21]

The third compound may be represented by Formula 3a or 3b, and due to its high Tg and good thermal stability, the third compound may be used in a hole related layer between the emission layer and the first electrode of an organic light-emitting diode:

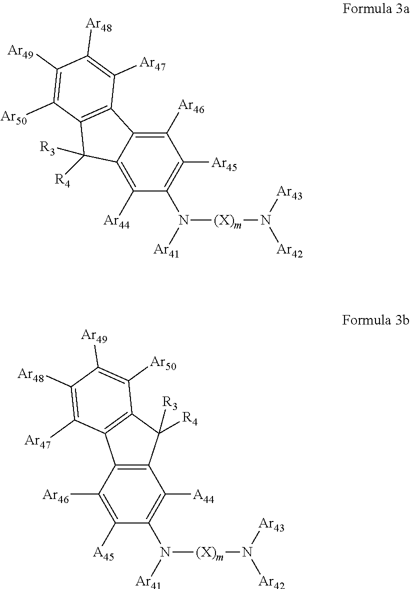

In Formula 3a and 3b, Ar₄₁ to Ar₅₀, R₃ and R₄, X, and m are the same as defined above.

For example, each of Ar₄₁ to Ar₅₀ may be independently one of a substituted or unsubstituted C₁-C₃₀ alkyl group, a substituted or unsubstituted C₅-C₃₀ aryl group, or a substituted or unsubstituted C₂-C₃₀ heteroaryl group.

For example, each of R₃ and R₄ may be independently a substituted or unsubstituted C₁-C₃₀ alkyl group, a substituted or unsubstituted C₅-C₃₀ aryl group, or a substituted or unsubstituted C₂-C₃₀ heteroaryl group.

The third compound may be a compound represented by one of Formula 6a or 6b below:

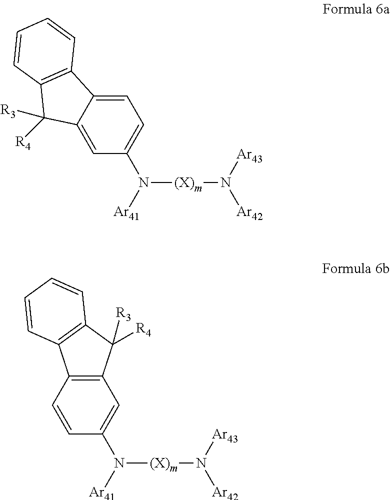

In Formulae 6a and 6b, each of Ar₄₁, Ar₄₂ and Ar₄₃ may be independently one of a hydrogen atom, a deuterium atom, a halogen atom, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group. Each of R₃ and R₄ may be independently one of a substituted or unsubstituted methyl group, a substituted or unsubstituted ethyl group, a substituted or unsubstituted propyl group, a substituted or unsubstituted butyl group, or a substituted or unsubstituted phenyl group. X may be one of a substituted or unsubstituted phenylene group, a substituted or unsubstituted biphenylene group, a substituted or unsubstituted naphthylene group, a substituted or unsubstituted anthrylene group, a substituted or unsubstituted phenanthrenylene group, or a substituted or unsubstituted fluorenylene group. X may optionally bind to Ar₄₂ or Ar₄₃ to form a ring, and m may be an integer of 1 or 2.

In the formulae above, when m is 2, a plurality of X are present and the plurality of X may be identical to or different from each other.

A highest occupied molecular orbit (HOMO) energy level of the third compound may be lower than −5.4 eV.

For example, the HOMO energy level of Compound 52, which will be described in detail later, is about −5.5 eV. The HOMO energy levels of CuPc and Mmtdata, which are materials conventionally used in forming a hole transport layer, are −5.2 eV and −5.1 eV, respectively. That is, the HOMO energy level of the third compound is lower than those of CuPc and Mmtdata. If the HOMO energy level of the third compound satisfies the range described above, hole injection in a direction from the first electrode to the emission layer may be improved.

For example, the third compound may be any one of Compounds 51 to 60 below, but is not limited thereto:

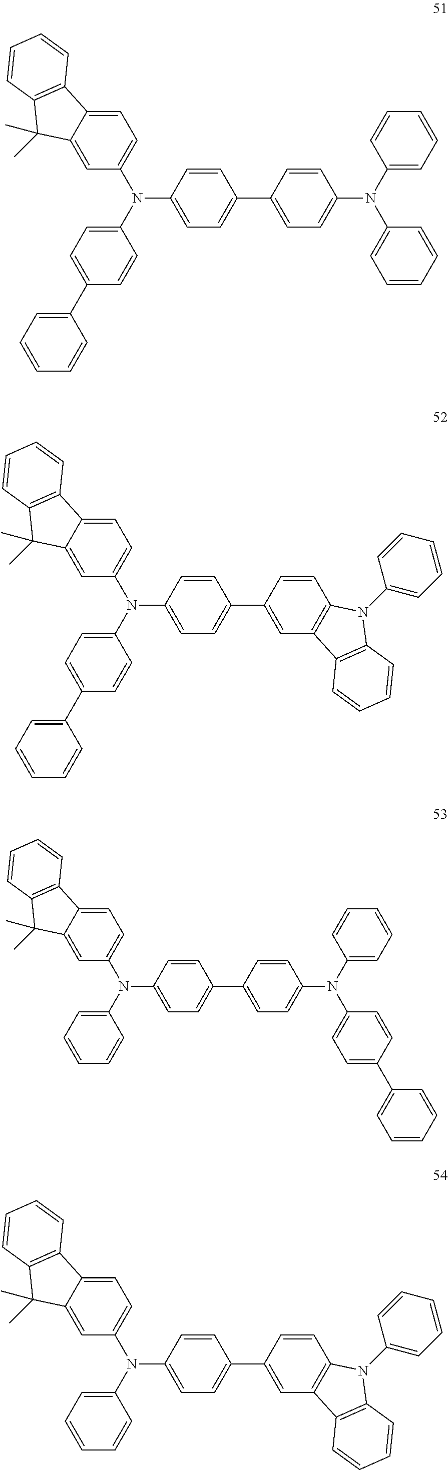 [SMILES: CC1(C)c2ccccc2-c2ccc(N(c3ccc(-c4ccccc4)cc3)c3ccc(-c4ccc(N(c5ccccc5)c5ccccc5)cc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc(N(c5ccccc5)c5ccc(-c6ccccc6)cc5)cc4)cc3)cc21 ; CC1(C)c2ccccc2-c2ccc(N(c3ccccc3)c3ccc(-c4ccc5c(c4)c4ccccc4n5-c4ccccc4)cc3)cc21]

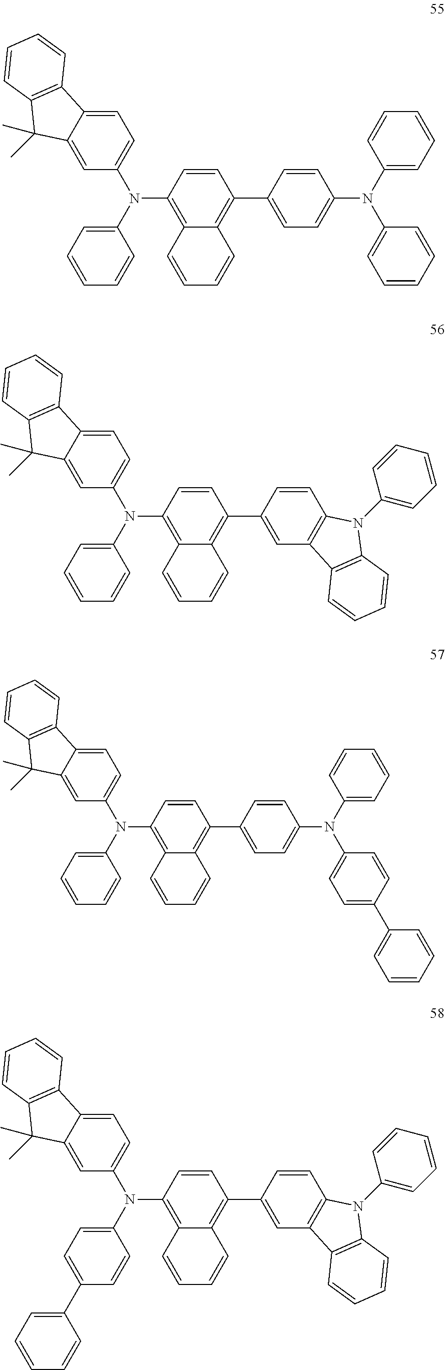 [SMILES: CC1(C)c2ccccc2-c2ccc(N(c3ccccc3)c3ccc(-c4ccc(N(c5ccccc5)c5ccccc5)cc4)c4ccccc34)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccccc3)c3ccc(-c4ccc(N(c5ccccc5)c5ccc(-c6ccccc6)cc5)cc4)c4ccccc34)cc21 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21]

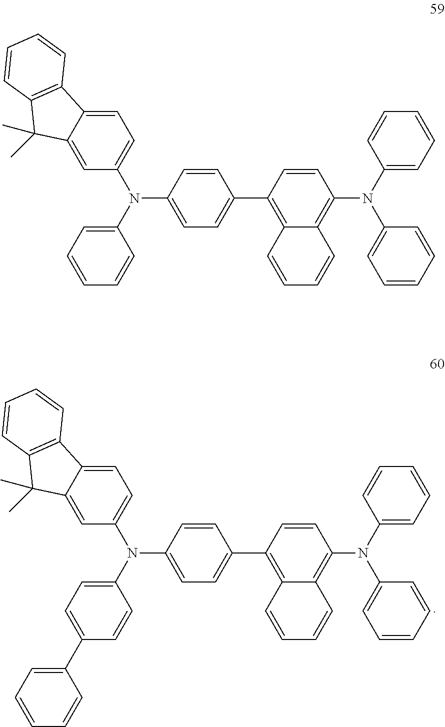 [SMILES: CC1(C)c2ccccc2-c2ccc(N(c3ccccc3)c3ccc(-c4ccc(N(c5ccccc5)c5ccccc5)c5ccccc45)cc3)cc21 ; CC1(C)c2ccccc2-c2ccc(N(c3ccc(-c4ccccc4)cc3)c3ccc(-c4ccc(N(c5ccccc5)c5ccccc5)c5ccccc45)cc3)cc21]

The term “substituted A” in the term “substituted or unsubstituted A” (where A is an arbitrary substituent) used herein refers to a case in which one or more hydrogen atoms of the “A” are substituted with one of a deuterium atom, a halogen atom, a hydroxyl group, a cyano group, a nitro group, a silyl group, a carboxylic acid group or a salt derivative thereof group, a sulfonic acid group or a salt derivative thereof, a phosphoric acid group or a salt derivative thereof, a C1-C30 alkyl group, a C2-C30 alkenyl group, a C2-C30 alkynyl group, a C1-C30 alkoxy group, a C3-C30 cycloalkyl group, a C3-C30 cycloalkenyl group, a C5-C30 aryl group, a C5-C30 aryloxy group, a C5-C30 arylthio group, a C2-C30 heteroaryl group, or a group represented by N(Q1)(Q2).” In this regard, each of Q1 and Q2 may be independently one of a hydrogen atom, a deuterium atom, a halogen atom, a hydroxyl group, a cyano group, an amino group, a nitro group, a carboxyl group, a silyl group, a C1-C30 alkyl group, a C2-C30 alkenyl group, a C2-C30 alkynyl group, a C1-C30 alkoxy group, a C3-C30 cycloalkyl group, a C3-C30 cycloalkenyl group, a C5-C30 aryl group, a C5-C30 aryloxy group, a C5-C30 arylthio group, and a C5-C30 heteroaryl group.

In the organic light-emitting diode, the emission layer includes the first compound and the second compound, and the first organic layer between the first electrode and the emission layer includes the third compound. Thus, thermal stability between the emission layer and the first organic layer is improved, and hole injection from the first electrode to the emission layer is improved. Thus, the efficiency and lifespan of the organic light-emitting diode are substantially increased.

An amount of the third compound included in the organic light-emitting diode may be about 30 to about 100 parts by weight based on 100 parts by weight of the first organic layer. If the amount of the third compound is greater than about 30 parts by weight, the effect achieved by the inclusion of the third compound having good thermal stability is appropriate.

The first organic layer of the organic light-emitting diode may include at least one of a hole injection layer, a hole transport layer, and a functional layer having both hole injection and hole transport functions. That is, the first organic layer including the third compound may be used as a hole injection layer, a hole transport layer, or a functional layer having both hole injection and hole transport functions to improve the hole injection characteristics.

For example, the first organic layer may be a hole transport layer, and a hole injection layer may be located between the first organic layer and the first electrode.

The first organic layer may further include a charge generation material. In this case, the charge generation material may include at least one of a quinone derivative, a metal oxide, or a cyano group-containing compound. The at least one of a quinone derivative, a metal oxide, and a cyano group-containing compound are each used as a p-dopant to generate charges between the first electrode and the emission layer to improve hole injection characteristics. Nonlimiting examples of the charge generation material include quinone derivatives, such as tetracyanobenzoquinonedimethane (TCNQ) and 2,3,5,6-tetrafluoro-tetracyano-1,4-benzoquinonedimethane (F4-CTNQ); metal oxides, such as tungsten oxide and molybdenum oxide; and cyano group-containing compounds, such as Compound 101 below.

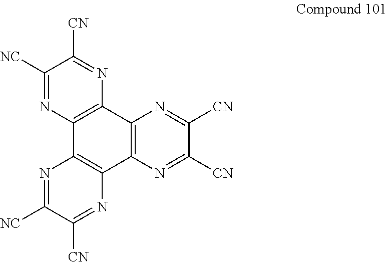 [SMILES: N#Cc1nc2c3nc(C#N)c(C#N)nc3c3nc(C#N)c(C#N)nc3c2nc1C#N]

The first organic layer may be formed by depositing the third compound, or coating the third compound prepared in a solution form. The latter process is a wet process.

In the organic light-emitting diode, the first compound may be used as a fluorescent host material and the second compound may be used as a fluorescent dopant material.

Using the first compound as a fluorescent host material and the second compound as a fluorescent dopant may suppress heat generation and crystallization in the emission layer.

The organic light-emitting diode may include a green emission layer. The first compound and the second compound may be used in the green emission layer.

The organic light-emitting diode may include, between the emission layer and the second electrode, at least one of an electron injection layer, an electron transport layer, and a functional layer having both electron injection and electron transport functions. For example, the organic light-emitting diode may have a structure of first electrode/hole injection layer/hole transport layer/emission layer/electron transport layer/electron injection layer/second electrode.

At least one of the electron injection layer, the electron transport layer, and the functional layer having both electron injection and electron transport functions included in the organic light-emitting diode may include an electron transport material and a metal complex. The electron transport material may be any known electron transport material and the metal complex may be a Li complex. Non-limiting examples of the Li complex include lithium quinolate (LiQ) and Compound 102 below:

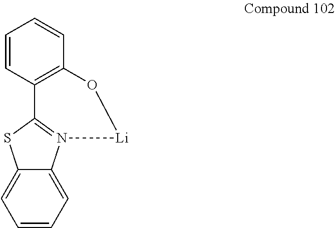

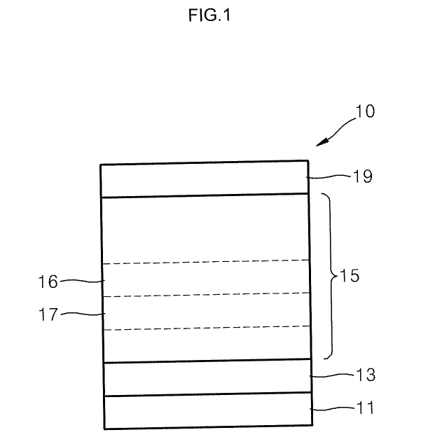

Hereinafter, a method of producing the organic light-emitting diode is described with reference to FIG. 1. However, the structure of the organic light-emitting diode is not limited to the structure of FIG. 1.

FIG. 1 is a schematic cross-sectional view of an organic light-emitting diode 10 according to an embodiment of the present invention.

The organic light-emitting diode 10 includes a first substrate 11, a first electrode 13, an organic layer 15, and a second electrode 19. For example, the organic light-emitting diode 10 may be a top emission organic light-emitting device.

The first substrate 11 may be a glass or transparent plastic substrate with good mechanical strength, thermal stability, transparency, surface smoothness, ease of handling, and water repellency. The first electrode 13 may be formed by depositing or sputtering a first electrode material on the first substrate 11. If the first electrode 13 is an anode, to allow holes to be injected thereinto easily, the first electrode material may be selected from materials having a high work function. Also, the first electrode 13 may be a reflective electrode. In this case, as the first electrode material, magnesium (Mg), silver (Ag), aluminum (Al), aluminum-lithium (Al—Li), calcium (Ca), silver:ITO (Ag:ITO), magnesium:indium (Mg:In) or magnesium:silver (Mg:Ag), etc. may be used. The first electrode 13 may be a single layer or a multi-layer that includes two or more layers, but is not limited thereto.

The organic layer 15 is located on the first electrode 13. The organic layer 15 may include a hole injection layer, a hole transport layer, a buffer layer, an emission layer 16, an electron transport layer, and an electron injection layer. A first organic layer 17 may be a hole injection layer or a hole transport layer between the emission layer 16 and the first electrode 13.

A hole injection layer (HIL) may include at least one of the third compound and a HIL material. The HIL material may be any known hole injecting material. Non-limiting examples of the HIL material include N,N′-diphenyl-N,N′-bis-[4-(phenyl-m-tolyl-amino)-phenyl]-biphenyl-4,4′-diamine (DNTPD), a phthalocyanine compound, such as copperphthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), (polyaniline)/poly(4-styrenesulfonate)(PANI/PSS), etc.

A hole transport layer (HTL) may be formed on the HIL. The HTL may include at least one of the third compound and a HTL material. The HTL material may be any known HTL material. Non-limiting examples thereof include carbazole derivatives, such as N-phenyl carbazole derivatives or polyvinylcarbazole derivatives, N,N′-bis(3-methylphenyl)-N,N′-diphenyl-[1,1-biphenyl]-4,4′-diamine (TPD), 4,4′,4″-tris(N-carbazolyl)triphenylamine (TCTA) or N,N′-di(1-naphthyl)-N,N′-diphenylbenzidine (NPB), etc.

A buffer layer may be between at least one of the HIL and HTL and the emission layer 16. The buffer layer may compensate for the optical resonance distance according to the wavelength of light emitted from the emission layer 16 to increase efficiency. The buffer layer may include at least one of a known hole injection material and a known hole transport material.

The emission layer (EML) 16 may be formed on the HTL or the buffer layer. The EML 16 may include the first compound and the second compound. For example, the first compound may be used as a host and the second compound may be used as a dopant. If the EML 16 includes a host and a dopant, typically, an amount of the dopant may be about 0.01 to about 15 parts by weight based on 100 parts by weight of the host, but is not limited thereto.

An electron transport layer (ETL) may be formed on the EML 16. The ETL may include an ETL material. The ETL material may stably transport electrons injected from an electron injection electrode (cathode) and may be any known material. Example of the ETL material include quinoline derivatives, such as tris(8-quinolinolate)aluminum (Alq3), TAZ, Balq, beryllium bis(benzoquinolin-10-olate)(Bebq₂), and ADN.

An electron injection layer (EIL) may be formed on the ETL and may include a material that allows electrons to be easily injected from the anode. The EIL may include an EIL material. The EIL material may be any known material, such as LiF, NaCl, CsF, Li₂O, or BaO.

The second electrode 19 is located on the organic layer 15. The second electrode 19 may be a cathode that constitutes an electron injection electrode. Examples of materials for the second electrode include low work function metals, alloys, electrically conductive compounds, and mixtures thereof. The second electrode 19 may be a transmissive electrode. For example, lithium (Li), magnesium (Mg), aluminum (Al), aluminum-lithium (Al—Li), calcium (Ca), magnesium:indium (Mg:In), or magnesium:silver (Mg:Ag) may be formed as a thin film, or ITO or IZO may be used.

According to embodiments of the present invention, the organic light-emitting diode may be included in a flat panel display device including a transistor. Accordingly, a flat panel display device according to an embodiment of the present invention includes: a transistor including a source, a drain, a gate, and an activation layer; and the organic light-emitting diode. The first electrode of the organic light-emitting diode is electrically connected to one of the source or the drain.

The activation layer of the transistor may be an amorphous silicon layer, a crystalline silicon layer, an organic semiconductor layer, an oxide semiconductor layer, or the like.

Hereinafter, an organic light-emitting diode according to embodiments of the present invention will be described in detail with reference to the following Examples. However, the Examples are presented for illustrative purposes only and do not limit the scope of the invention.

### Example 1

As an anode, an Ag film and an ITO film (Ag:ITO=1000 Å:200 Å) were sequentially formed on a glass substrate, and sonicated with isopropyl alcohol and pure water for 5 minutes each, and then ultraviolet rays were irradiated thereto for 30 minutes, followed by exposure to ozone. Then, the glass substrate was installed on a vacuum deposition apparatus.

2-TNATA was vacuum deposited on the glass substrate to form a HIL having a thickness of 600 Å, and then, Compound 52 was vacuum deposited on the HIL to form a HTL having a thickness of 300.

Compound 11 as a host and Compound 36 as a dopant were co-deposited in a weight ratio of 97:3 on the HTL to form a green EML having a thickness of 200 Å.

Subsequently, Alq3 was vacuum deposited on the green EML to form an ETL having a thickness of 250 Å. Then, LiF (as a halogenated alkali metal) was vacuum deposited on the ETL to form an EIL having a thickness of 10 Å, followed by vacuum depositing Mg:Ag (Mg:Ag=10:1) thereon to form a cathode having a thickness of 250 Å, thereby completing the manufacture of an organic light-emitting diode.

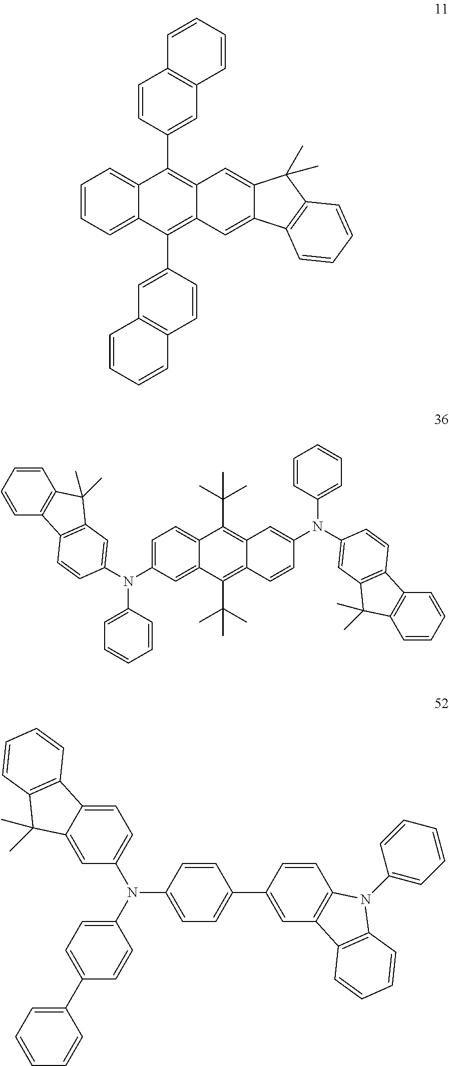

### Comparative Example 1

An organic light-emitting diode was manufactured in the same manner as in Example 1, except that the HTL was formed using 4,4′-bis[N-(1-naphthyl)-N-phenyl amino]biphenyl (NPB) instead of Compound 52, and the EML was formed using Compound 11 as a host and C545T (instead of Compound 36) as a dopant.

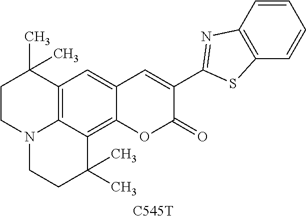

### Comparative Example 2

An organic light-emitting diode was manufactured in the same manner as in Example 1, except that the HTL was formed using 4,4′-bis[N-(1-naphthyl)-N-phenyl amino]biphenyl (NPB) instead of Compound 52, and the EML was formed using Alq3 (instead of Compound 11) as a host and Compound 36 as a dopant.

### Comparative Example 3

An organic light-emitting diode was manufactured in the same manner as in Example 1, except that the EML was formed using Alq3 (instead of Compound 11) as a host and C545T (instead of Compound 36) as a dopant.

### Evaluation Example

The driving voltage, current efficiency, color coordinates, and luminance of the organic light-emitting diodes manufactured according to Example 1 and Comparative Examples 1 to 3 were evaluated using a PR650 (Spectroscan) Source Measurement Unit (product of PhotoResearch Company), and the results thereof are shown in Table 1 below.

TABLE 1

| | | Current | | |
|---|---|---|---|---|
| | Driving | efficiency | Color | Luminance |
| | voltage (V) | (cd/A) | coordinates | (cd/m²) |
| Example1 | 4.1 | 44.7 | (0.21, 0.74) | 3,900 |
| Comparative | 3.7 | 36.4 | (0.22, 0.74) | 3,900 |
| Example1 | | | | |
| Comparative | 4.1 | 27.1 | (0.16, 0.74) | 3,900 |
| Example2 | | | | |
| Comparative | 4.1 | 39.2 | (0.22, 0.73) | 3,900 |
| Example3 | | | | |

Referring to Table 1, it is confirmed that the organic light-emitting diode of Example 1 has higher current efficiency than the organic light-emitting diodes of Comparative Examples 1 to 3.

The organic light-emitting diode of Comparative Example 1 is different from the organic light-emitting diode of Example 1 in that although the same host material is used, the HTL material and the dopant material are different from those used in Example 1. The organic light-emitting diode of Comparative Example 2 is different from the organic light-emitting diode of Example 1 in that although the same dopant material is used, the HTL material and the host material are different from those used in Example 1. The organic light-emitting diode of Comparative Example 3 is different from the organic light-emitting diode of Example 1 in that although the same HTL material is used, the host material and the dopant material are different from those used in Example 1. From the results, it is confirmed that when a HTL material represented by Formula 3a or 3b, a host material represented by Formula 1 and a dopant material represented by Formula 2 are all used (as in Example 1), higher efficiency is obtained than when at least one of those material is not used.

An organic light-emitting diode according to an embodiment of the present invention includes materials with good thermal stability, and due to the inclusion of such materials, the hole injection and mobility characteristics of the OLED are improved, and the thermal stability at a boundary of the EML is improved.

While the present invention has been illustrated and described with reference to certain exemplary embodiments, it will be understood by those of ordinary skill in the art that various changes may be made to the described embodiments without departing from the spirit and scope of the present invention as defined by the following claims.

What is claimed is:

1. An organic light-emitting diode comprising:
a first electrode,
a second electrode facing the first electrode,
an emission layer between the first and second electrodes and comprising a first compound and a second compound, and
a first organic layer between the emission layer and the first electrode and comprising a third compound,
wherein the first compound comprises a compound represented by Formula 1 below, the second compound comprises a compound represented by Formula 2 below, and the third compound comprises a compound represented by Formula 3a or 3b below: 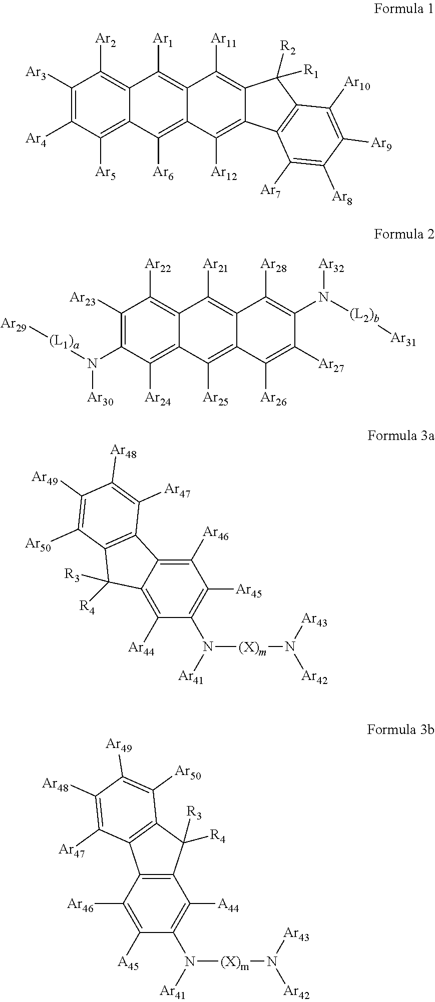
wherein in Formulae 1, 2, 3a and 3b,
each of Ar₁ to Ar₁₂, Ar₂₁ to Ar₃₂ and Ar₄₁ to Ar₅₀ is independently one of a hydrogen atom, a deuterium atom, a halogen atom, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, a substituted or unsubstituted C₅-C₃₀ aryloxy group, a substituted or unsubstituted C₅-C₃₀ arylthio group, a substituted or unsubstituted C₂-C₃₀ heteroaryl group, or a group represented by N(Q₁)(Q₂), wherein each of Q₁ and Q₂ is independently one of a hydrogen atom, a deuterium atom, a halogen atom, a hydroxyl group, a cyano group, an amino group, a nitro group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, a substituted or unsubstituted C₅-C₃₀ aryloxy group, a substituted or unsubstituted C₅-C₃₀ arylthio group, or a substituted or unsubstituted C₂-C₃₀ heteroaryl group, wherein at least one of Ar₂₉ to Ar₃₂ is a fluorenyl group,
each of R₁ to R₄ is independently one of a hydrogen atom, a deuterium atom, a halogen atom, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₅-C₃₀ aryl group, or a substituted or unsubstituted C₂-C₃₀ heteroaryl group,
each of L₁, L₂, and X is independently a substituted or unsubstituted C₅-C₆₀ arylene group or a substituted or unsubstituted C₂-C₃₀ heteroarylene group, wherein X optionally binds to Ar₄₂ or Ar₄₃ to form a ring,
each of a and b is independently an integer of 0 to 3, and
m is an integer of 1 to 3.

2. The organic light-emitting diode of claim 1, wherein each of Ar₁ to Ar₁₂, Ar₂₁ to Ar₃₂ and Ar₄₁ to Ar₅₀ is independently a substituted or unsubstituted C₁-C₃₀ alkyl group, a substituted or unsubstituted C₅-C₃₀ aryl group, or a substituted or unsubstituted C₂-C₃₀ heteroaryl group.

3. The organic light-emitting diode of claim 1, wherein each of R₁ to R₄ is independently a substituted or unsubstituted C₁-C₃₀ alkyl group, a substituted or unsubstituted C₅-C₃₀ aryl group, or a substituted or unsubstituted C₂-C₃₀ heteroaryl group.

4. The organic light-emitting diode of claim 1, wherein the first compound comprises a compound represented by Formula 4 below: 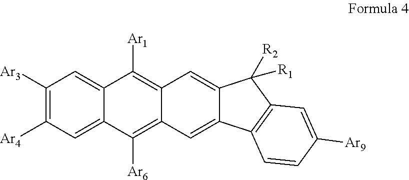
wherein in Formula 4,
each of Ar₁, Ar₃, Ar₄, Ar₆ and Ar₉ is independently a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group, and
each of R₁ and R₂ is independently a substituted or unsubstituted methyl group, a substituted or unsubstituted ethyl group, a substituted or unsubstituted propyl group, a substituted or unsubstituted butyl group, or a substituted or unsubstituted phenyl group.

5. The organic light-emitting diode of claim 1, wherein the second compound comprises a compound represented by one of Formulae 5a to 5h below: 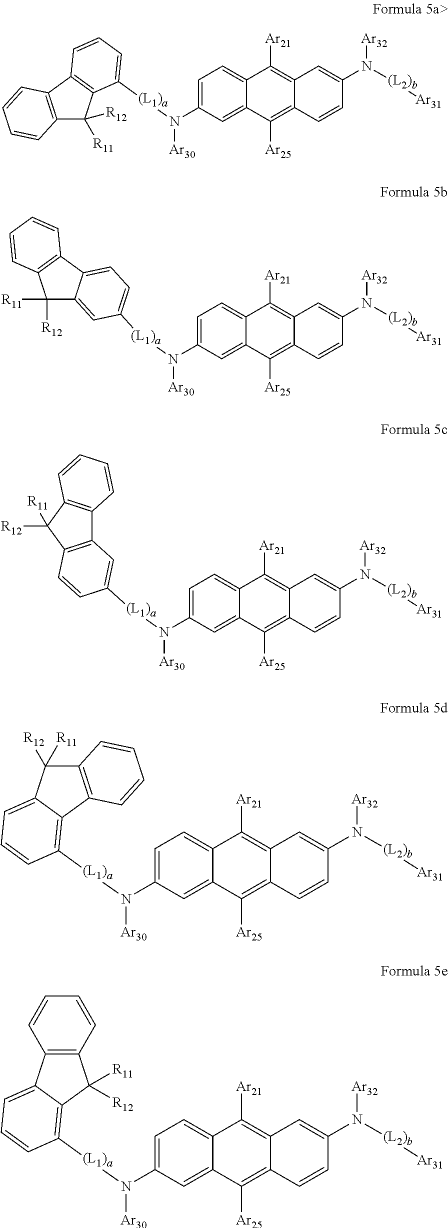 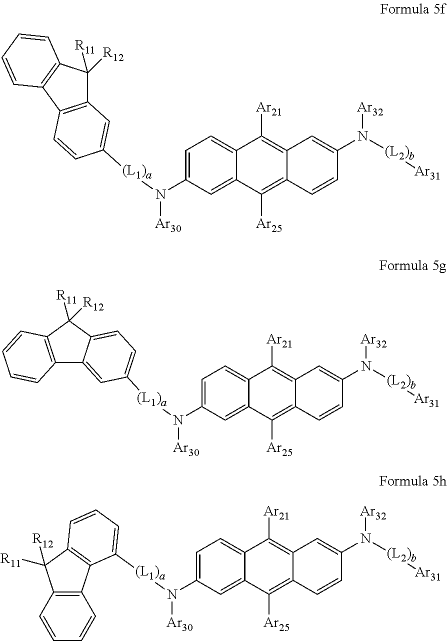
wherein in Formulae 5a to 5h,
each of Ar₂₁, Ar₂₅, Ar₃₀, Ar₃₁, and Ar₃₂ is independently a hydrogen atom, a deuterium atom, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted indolyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group,
each of R₁₁ and R₁₂ is independently a substituted or unsubstituted methyl group, a substituted or unsubstituted ethyl group, a substituted or unsubstituted propyl group, a substituted or unsubstituted butyl group, or a substituted or unsubstituted phenyl group,
each of L₁ and L₂ is independently a substituted or unsubstituted phenylene group, a substituted or unsubstituted biphenylene group, a substituted or unsubstituted naphthylene group, a substituted or unsubstituted anthrylene group, a substituted or unsubstituted phenanthrenylene group, or a substituted or unsubstituted fluorenylene group, and
each of a and b is independently an integer of 0 or 1.

6. The organic light-emitting diode of claim 1, wherein the third compound comprises a compound represented by Formula 6a or 6b below: 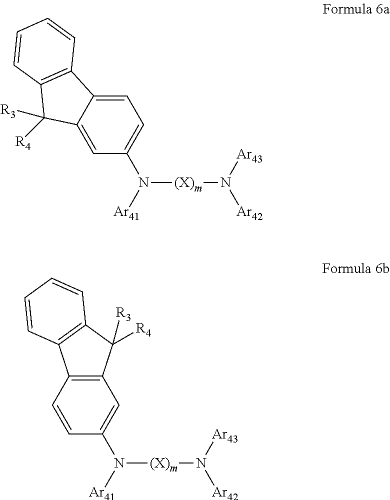
wherein in Formulae 6a and 6b,
each of Ar₄₁, Ar₄₂ and Ar₄₃ is independently a hydrogen atom, a deuterium atom, a halogen atom, a substituted or unsubstituted methyl group, a substituted or unsubstituted ethyl group, a substituted or unsubstituted propyl group, a substituted or unsubstituted butyl group, a substituted or unsubstituted phenyl group, a substituted or unsubstituted biphenyl group, a substituted or unsubstituted naphthyl group, a substituted or unsubstituted anthryl group, a substituted or unsubstituted phenanthrenyl, a substituted or unsubstituted fluorenyl group, a substituted or unsubstituted pyrenyl group, a substituted or unsubstituted carbazolyl group, a substituted or unsubstituted dibenzofuranyl group, a substituted or unsubstituted dibenzothiophenyl group, or a substituted or unsubstituted benzocarbazolyl group,
each of R₃ and R₄ is independently one of a substituted or unsubstituted methyl group, a substituted or unsubstituted ethyl group, a substituted or unsubstituted propyl group, a substituted or unsubstituted butyl group, or a substituted or unsubstituted phenyl group,
X is a substituted or unsubstituted phenylene group, a substituted or unsubstituted biphenylene group, a substituted or unsubstituted naphthylene group, a substituted or unsubstituted anthrylene group, a substituted or unsubstituted phenanthrenylene group, or a substituted or unsubstituted fluorenylene group, wherein X optionally binds to Ar₄₂ or Ar₄₃ to form a ring, and
m is an integer of 1 or 2.

7. The organic light-emitting diode of claim 1, wherein a highest occupied molecular orbital (HOMO) energy level of the third compound is lower than −5.4 eV.

8. The organic light-emitting diode of claim 1, wherein the first compound comprises one of Compounds 11 to 20:

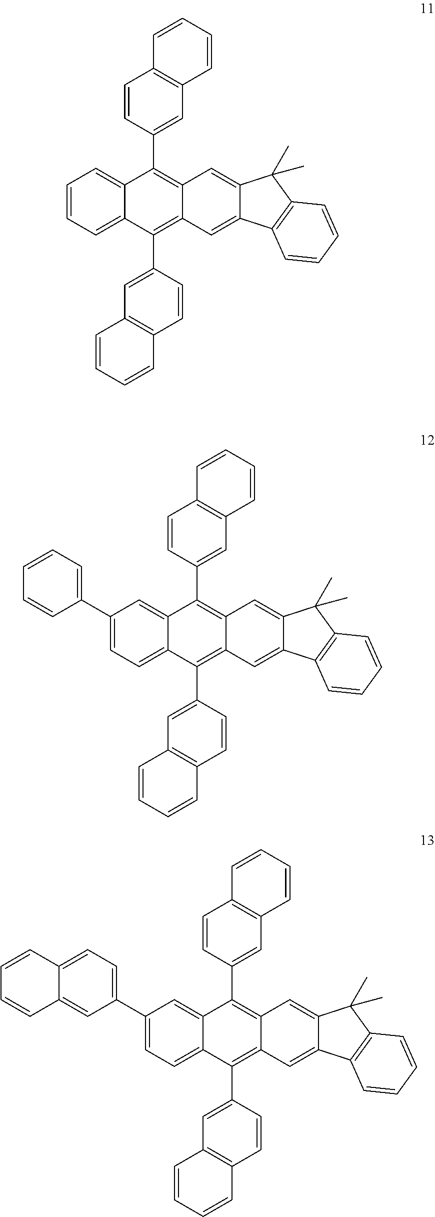

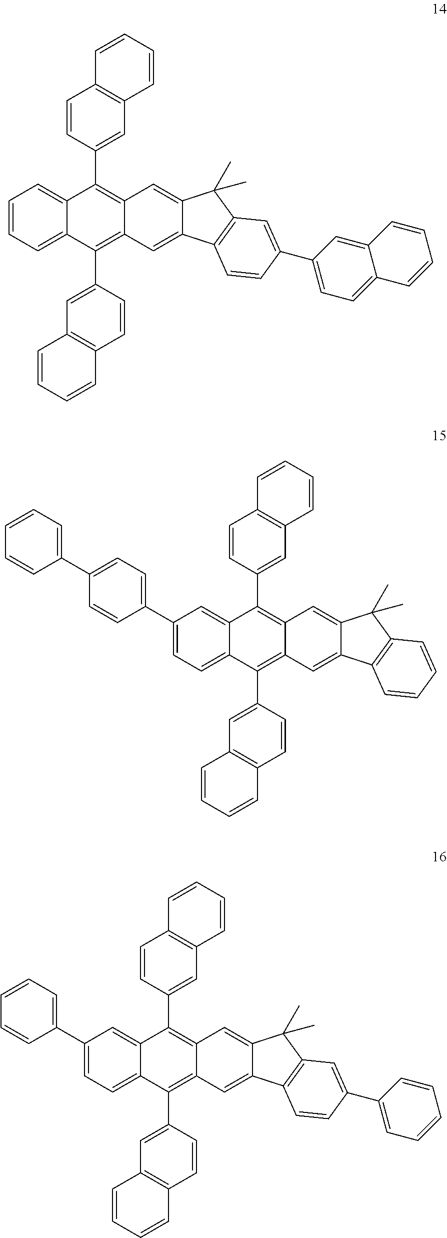

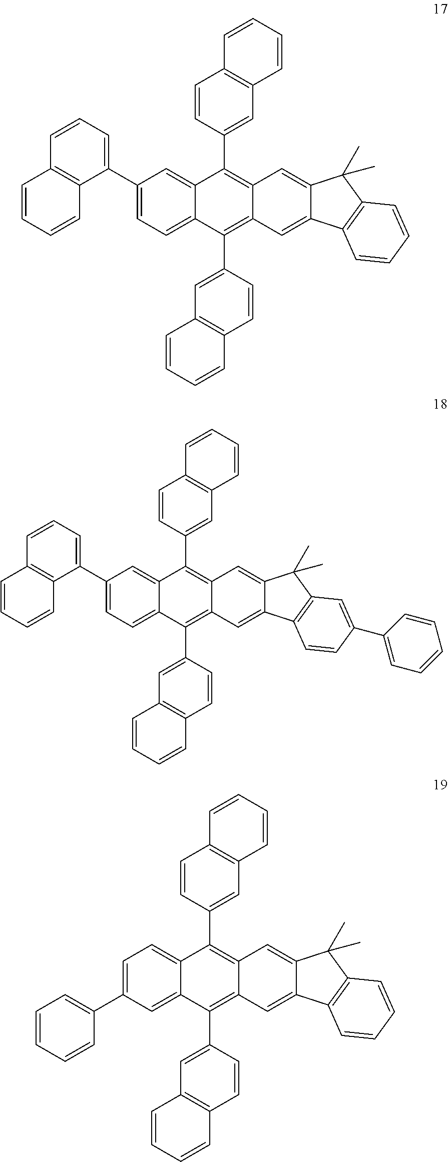

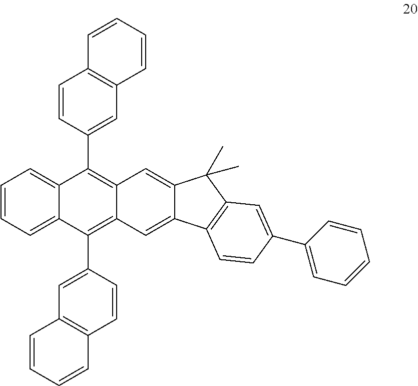 [SMILES: CC1(C)c2cc(-c3ccccc3)ccc2-c2cc3c(-c4ccc5ccccc5c4)c4ccccc4c(-c4ccc5ccccc5c4)c3cc21]

9. The organic light-emitting diode of claim 1, wherein the second compound comprises one of Compounds 31 to 45 below:

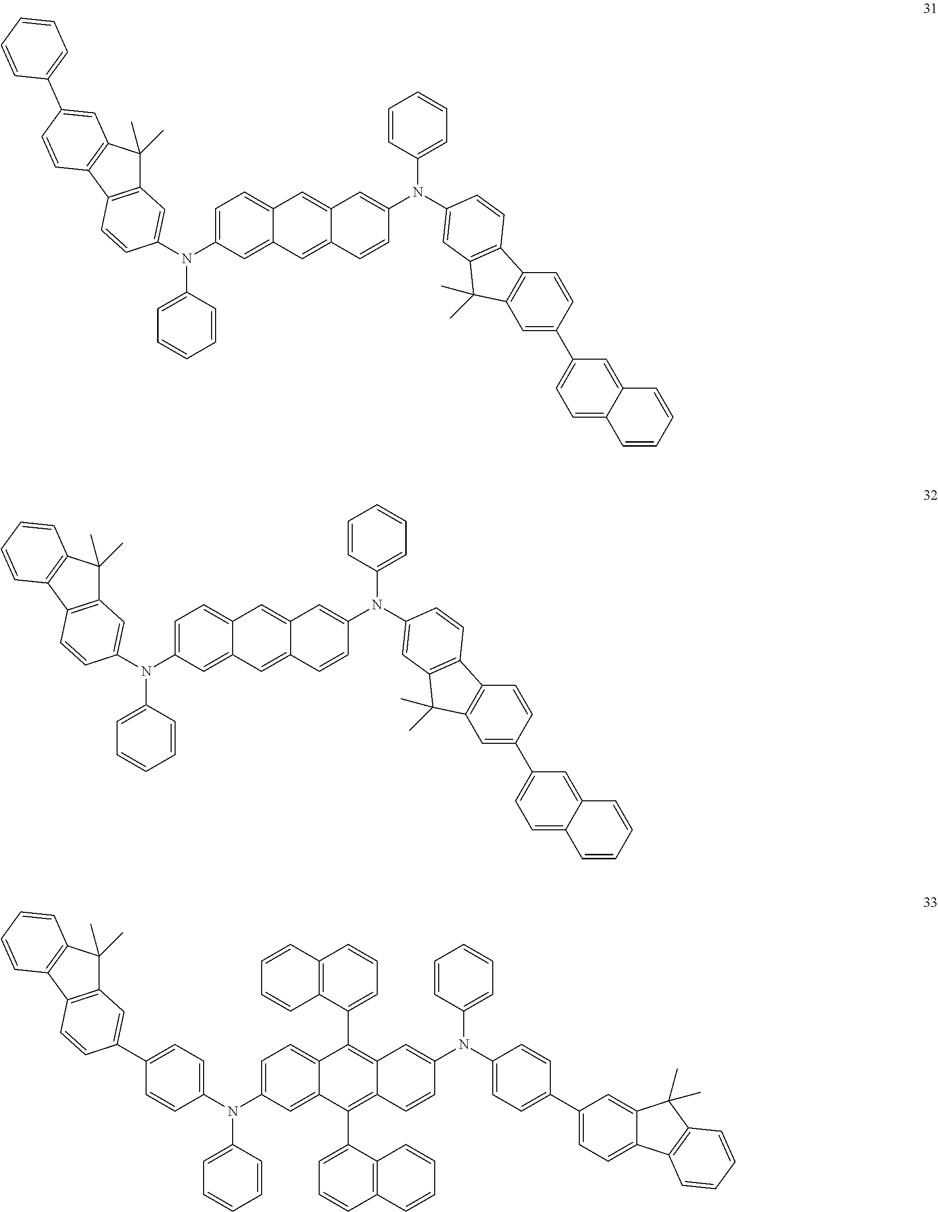 [SMILES: CC1(C)c2cc(-c3ccccc3)ccc2-c2ccc(N(c3ccccc3)c3ccc4cc5cc(N(c6ccccc6)c6ccc7c(c6)C(C)(C)c6cc(-c8ccc9ccccc9c8)ccc6-7)ccc5cc4c3)cc21 ; CC1(C)c2ccccc2-c2ccc(N(c3ccccc3)c3ccc4cc5cc(N(c6ccccc6)c6ccc7c(c6)C(C)(C)c6cc(-c8ccc9ccccc9c8)ccc6-7)ccc5cc4c3)cc21 ; CC1(C)c2ccccc2-c2ccc(-c3ccc(N(c4ccccc4)c4ccc5c(-c6cccc7ccccc67)c6cc(N(c7ccccc7)c7ccc(-c8ccc9c(c8)C(C)(C)c8ccccc8-9)cc7)ccc6c(-c6cccc7ccccc67)c5c4)cc3)cc21]

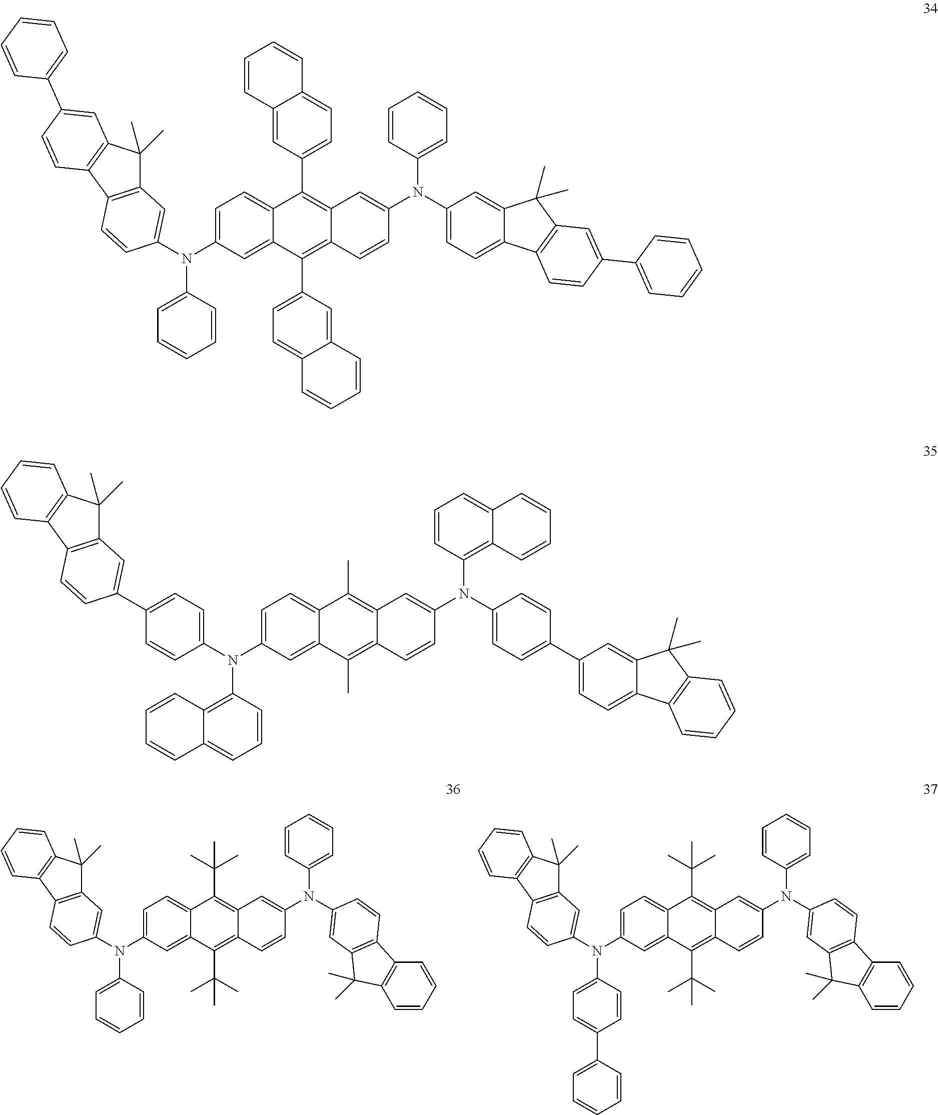

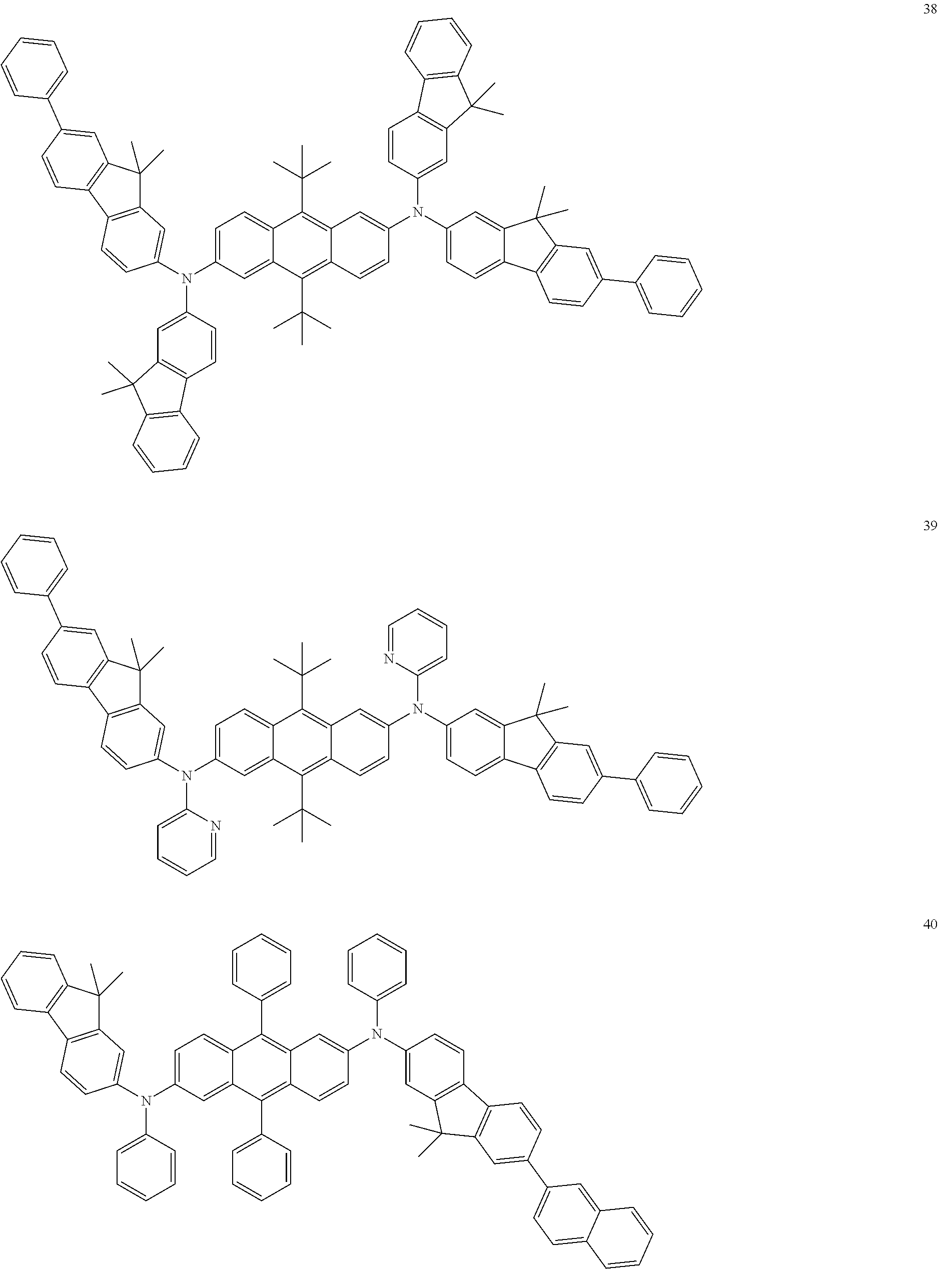 [SMILES: CC(C)(C)c1c2ccc(N(c3ccc4c(c3)C(C)(C)c3ccccc3-4)c3ccc4c(c3)C(C)(C)c3cc(-c5ccccc5)ccc3-4)cc2c(C(C)(C)C)c2ccc(N(c3ccc4c(c3)C(C)(C)c3ccccc3-4)c3ccc4c(c3)C(C)(C)c3cc(-c5ccccc5)ccc3-4)cc12 ; CC(C)(C)c1c2ccc(N(c3ccc4c(c3)C(C)(C)c3cc(-c5ccccc5)ccc3-4)c3ccccn3)cc2c(C(C)(C)C)c2ccc(N(c3ccc4c(c3)C(C)(C)c3cc(-c5ccccc5)ccc3-4)c3ccccn3)cc12 ; CC1(C)c2ccccc2-c2ccc(N(c3ccccc3)c3ccc4c(-c5ccccc5)c5cc(N(c6ccccc6)c6ccc7c(c6)C(C)(C)c6cc(-c8ccc9ccccc9c8)ccc6-7)ccc5c(-c5ccccc5)c4c3)cc21]

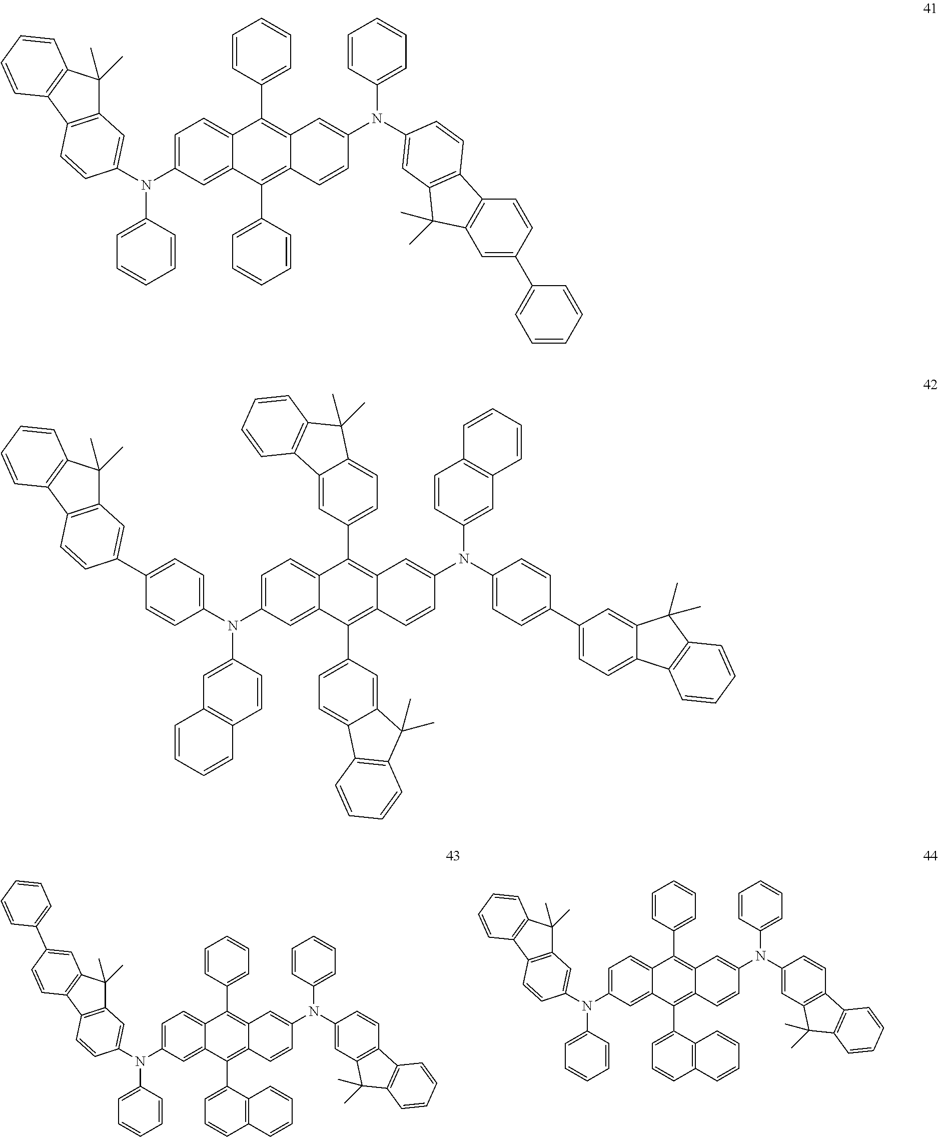

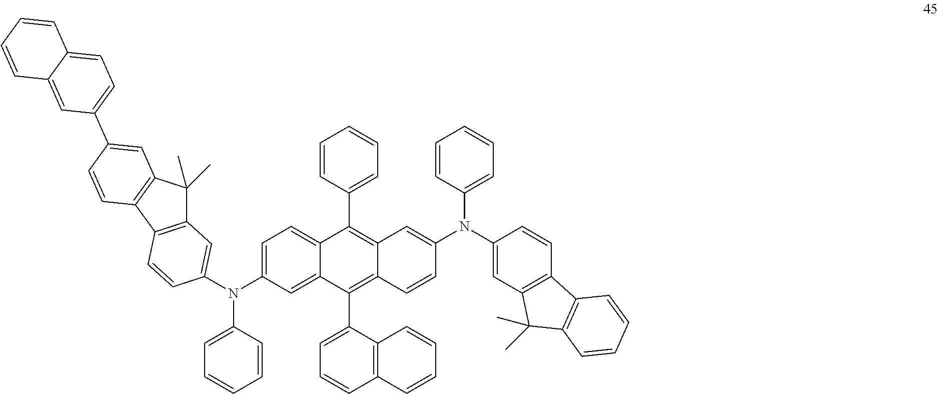 [SMILES: CC1(C)c2ccccc2-c2ccc(N(c3ccccc3)c3ccc4c(-c5cccc6ccccc56)c5cc(N(c6ccccc6)c6ccc7c(c6)C(C)(C)c6cc(-c8ccc9ccccc9c8)ccc6-7)ccc5c(-c5ccccc5)c4c3)cc21]

10. The organic light-emitting diode of claim 1, wherein the third compound comprises one of Compounds 51 to 60 below:

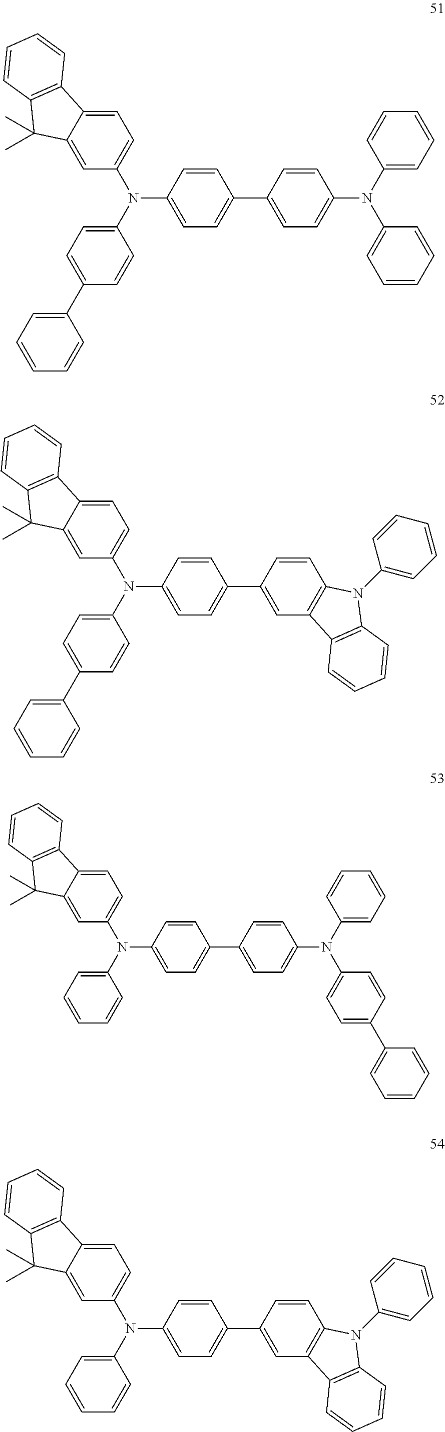 [SMILES: CC1(C)c2ccccc2-c2ccc(N(c3ccc(-c4ccccc4)cc3)c3ccc(-c4ccc(N(c5ccccc5)c5ccccc5)cc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc(N(c5ccccc5)c5ccc(-c6ccccc6)cc5)cc4)cc3)cc21 ; CC1(C)c2ccccc2-c2ccc(N(c3ccccc3)c3ccc(-c4ccc5c(c4)c4ccccc4n5-c4ccccc4)cc3)cc21]

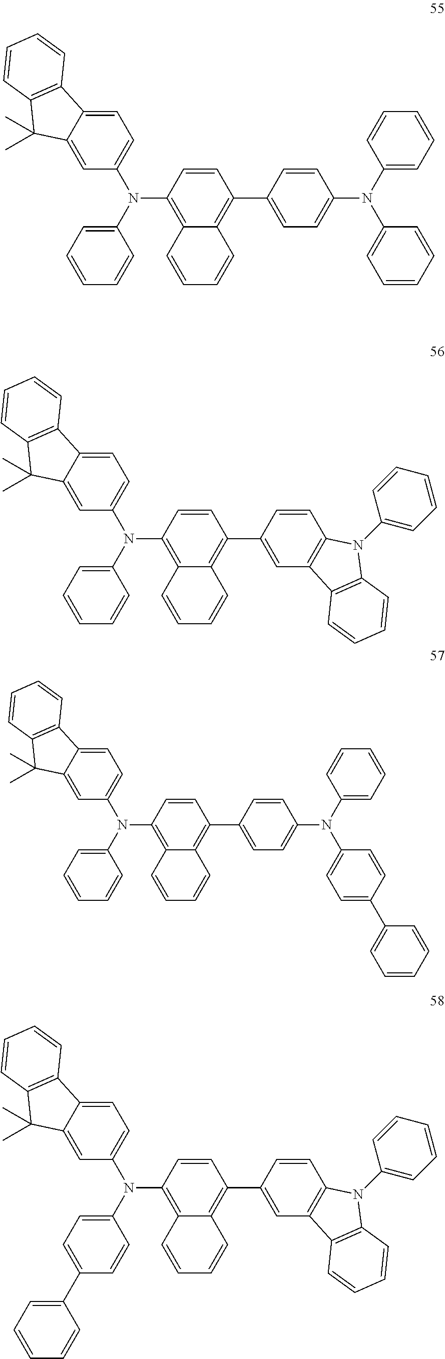 [SMILES: CC1(C)c2ccccc2-c2ccc(N(c3ccccc3)c3ccc(-c4ccc(N(c5ccccc5)c5ccccc5)cc4)c4ccccc34)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccccc3)c3ccc(-c4ccc(N(c5ccccc5)c5ccc(-c6ccccc6)cc5)cc4)c4ccccc34)cc21 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21]

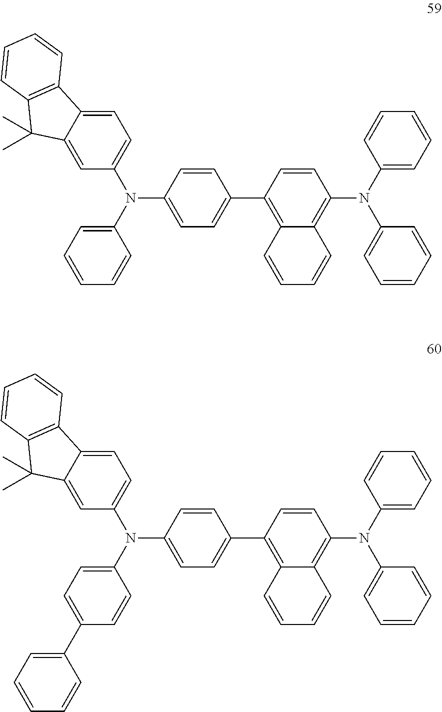 [SMILES: CC1(C)c2ccccc2-c2ccc(N(c3ccccc3)c3ccc(-c4ccc(N(c5ccccc5)c5ccccc5)c5ccccc45)cc3)cc21 ; CC1(C)c2ccccc2-c2ccc(N(c3ccc(-c4ccccc4)cc3)c3ccc(-c4ccc(N(c5ccccc5)c5ccccc5)c5ccccc45)cc3)cc21]

11. The organic light-emitting diode of claim 1, wherein an amount of the third compound is about 30 to about 100 parts by weight based on 100 parts by weight of the first organic layer.

12. The organic light-emitting diode of claim 1, wherein the first organic layer comprises at least one of a hole injection layer, a hole transport layer, or a functional layer having hole injection and hole transport functions.

13. The organic light-emitting diode of claim 1, wherein the first organic layer is a hole transport layer, and the organic light-emitting diode further comprises a hole injection layer between the first organic layer and the first electrode.

14. The organic light-emitting diode of claim 1, wherein the first organic layer further comprises a charge generation material, and the charge generation material comprises at least one of a quinone derivative, a metal oxide, or a cyano group-containing compound.

15. The organic light-emitting diode of claim 1, wherein the first organic layer is formed using a wet process.

16. The organic light-emitting diode of claim 1, wherein the first compound is a fluorescent host material and the second compound is a fluorescent dopant material.

17. The organic light-emitting diode of claim 1, wherein the emission layer comprises a green emission layer.

18. The organic light-emitting diode of claim 1, further comprising at least one additional layer between the emission layer and the second electrode, the at least one additional layer being selected from an electron injection layer, an electron transport layer, and a functional layer having electron injection and electron transport functions.

19. The organic light-emitting diode of claim 18, wherein the at least one additional layer comprises an electron transport material and a metal complex.

20. A flat panel display device comprising:
a transistor comprising a source, a drain, a gate, and an activation layer; and
the organic light-emitting diode of claim 1,
wherein the first electrode of the organic light-emitting diode is electrically connected to the source or the drain.
